(19) United States
(12) Patent Application Publication
(10) Pub. No.: US 2021/0149110 A1
(43) Pub. Date: May 20, 2021

(54) OPTICAL WAVEGUIDE-TYPE OPTICAL MULTIPLEXER, OPTICAL WAVEGUIDE-TYPE MULTIPLEXING LIGHT SOURCE OPTICAL DEVICE AND IMAGE PROJECTING DEVICE

(71) Applicant: University of Fukui, Fukui-shi (JP)

(72) Inventors: Toshio Katsuyama, Fukui-shi (JP); Shoji Yamada, Fukui-shi (JP)

(73) Assignee: University of Fukui, Fukui-shi (JP)

(21) Appl. No.: 17/159,476

(22) Filed: Jan. 27, 2021

Related U.S. Application Data
(63) Continuation of application No. PCT/JP2020/006480, filed on Feb. 19, 2020.

(30) Foreign Application Priority Data
Mar. 13, 2019 (JP) 2019-046162

(51) Int. Cl. G02B 6/12; G02B 26/10; G02B 26/08; G03B 21/20; G02B 6/125

(52) U.S. Cl. CPC G02B 6/12007; G02B 26/101; G03B 21/2033; G03B 21/2013; G02B 6/125; G02B 26/0816

(57) ABSTRACT

The invention relates to an optical waveguide-type optical multiplexer, an optical waveguide-type multiplexing light source device and an image projection device, where the intensity of a light beam emitted from a light source is attenuated to a desired value without installing an additional optical attenuator element. One of a plurality of optical waveguides on the light emission side for emitting light distributed/multiplexed in an optical multiplexer unit excluding an optical waveguide on the light emission side in which the greatest output light power can be gained for each wavelength from among the optical waveguides on the light emission side in the case where a plurality of light sources is driven is used as an optical waveguide for light emission.

### CROSS-REFERENCE TO RELATED APPLICATION

This application is a continuation application of International Application Number PCT/JP2020/006480 filed on Feb. 19, 2020, now pending, herein incorporated by reference. Further, this application is based upon and claims the benefit of priority from the prior Japanese Patent Application No. 2019-46162, filed on Mar. 13, 2019, entire contents of which are incorporated herein by reference.

### FIELD

The present invention relates to an optical waveguide-type optical multiplexer, an optical waveguide-type multiplexing light source optical device and an image projection device, and relates to, for example, a configuration for attenuating the intensity of a light beam emitted from a light source to a desired value without installing an additional optical attenuator element.

### BACKGROUND

Various forms of light beam multiplexing light sources have been known as conventional devices for multiplexing a plurality of light beams such as laser beams so as to radiate one beam. From among these, light beam multiplexing light source devices where semiconductor lasers and optical waveguide-type optical multiplexers are combined are characterized in that the device can be made compact and the power can be lowered, and thus are applied to a laser beam scanning-type color image projection device (see Patent Literature 1 through 3).

Conventional light beam multiplexing light sources where semiconductor lasers and optical waveguide-type optical multiplexers are combined include a light beam multiplexing light source for multiplexing laser beams of three primary colors as illustrated in Patent Literature 3, for example.

FIG. 28 is a schematic diagram illustrating the configuration of a conventional optical waveguide-type optical multiplexer made by the present inventors (see Patent Literature 2). The optical waveguide-type optical multiplexer has optical waveguides 23 through 25 for light input made of a core layer and a clad layer, an optical multiplexing unit 30 and an optical waveguide 28 on the light emission side, and the optical waveguide 23 for light input optically couples with the optical waveguide 24 for light input through optical couplers 31 and 32 in the optical multiplexing unit 30. The optical waveguide 25 for light input optically couples with the optical waveguide 24 for light input in an optical coupler 33 in the optical multiplexing unit 30.

A blue semiconductor laser chip 41, a green semiconductor laser chip 42 and a red semiconductor laser chip 43 are installed at the entrance ends of the optical waveguides 23 through 25 for light input that correspond to the respective colors. Here, light beams propagate through the core layer in the optical waveguides 23 through 25 for light input so as to be multiplexed in the optical waveguide-type optical multiplexer 30, and after that, the multiplexed light is emitted from the emission end of the optical waveguide 28 on the light emission side, which is an extended portion of the optical waveguide 24 for light input.

FIG. 29 is a schematic diagram illustrating a two-dimensional optical scanning device that has been proposed by the present inventors (see Patent Literature 6). An optical waveguide-type optical multiplexer 30 is provided on a substrate 85 on which a movable mirror unit 84 is formed, and a blue semiconductor laser chip 41, a green semiconductor laser chip 42 and a red semiconductor laser chip 43 are coupled with the optical waveguide-type optical multiplexer 30. Even in the case where the two-dimensional optical scanning device is integrated with the light sources for generating light beams, the total size after the integration can be made small because the movable mirror unit 84 is made compact. In particular, in the case where the light sources for light emission beams are semiconductor laser chips or optical waveguide-type optical multiplexers, these semiconductor laser chips or optical waveguide-type optical multiplexers can be formed on an Si substrate or a metal plate substrate, and therefore, such effects can be gained where the entire size after integration can be made small when the light sources and the two-dimensional optical scanning mirror device are formed on such a substrate.

FIG. 30 is a schematic diagram illustrating an image projection device that has been proposed by the present inventors (see Patent Literature 6). A two-dimensional scanning device as described above, a two-dimensional scanning control unit for two-dimensional scanning with emission light that has been emitted from a light source by applying a two-dimensional optical scanning signal to an electromagnetic coil 86, and an image formation unit for projecting onto a projection plane an image scanned with the emission light are combined. Here, the image projection device is described as an eyeglass-type retina scanning display.

In this image formation device, a control unit 90 has a sub-control unit 91, an operation unit 92, an external interface (I/F) 93, an R laser driver 94, a G laser driver 95, a B laser driver 96 and a two-dimensional scanning driver 97. The sub-control unit 91 is formed of a microcomputer that includes a CPU, a ROM and a RAM, for example. The sub-control unit 91 generates an R signal, a G signal, a B signal, a horizontal signal and a vertical signal that become elements for synthesizing an image on the basis of the image data supplied from an external device such as a PC via an external I/F 93. The sub-control unit 91 transmits an R signal to an R laser drive 94, a G signal to a G laser driver 95 and a B signal to a B laser driver 96, respectively. In addition, the sub-control unit 91 transmits a horizontal signal and a vertical signal to a two-dimensional scanning driver 97 so as to control a current to be applied to an electromagnetic coil 86, and thus controls the operation of a movable mirror unit 84.

The R laser driver 94 drives the red semiconductor laser chip 43 so that red laser light with a light quantity that corresponds to the R signal from the sub-control unit 91 is generated. The G laser driver 95 drives a green semiconductor laser chip 42 so that green laser light with a light quantity that corresponds to the G signal from the sub-control unit 91 is generated. The B laser driver 96 drives the blue semiconductor laser chip 41 so that blue laser light with a light quantity that corresponds to the B signal from the sub-control unit 91 is generated. It becomes possible to synthesize laser light having a desired color by adjusting the intensity ratio of the laser light of the respective colors.

The respective laser beams generated by the blue semiconductor laser chip 41, the green semiconductor laser chip 42 and the red semiconductor laser chip 43 are multiplexed in the optical multiplexing unit 30 in the optical waveguide-type optical multiplexer, and after that the multiplexed light is used for the two-dimensional scanning by means of the movable mirror unit 84. An image formed on a retina 100 is scanned with the multiplexed laser light, which is reflected from a concave reflecting mirror 98 so as to pass through a pupil 99.

### CITATION LIST

### Patent Literature

Patent Literature 1: Japanese Unexamined Patent Publication 2008-242207
Patent Literature 2: Japanese Unexamined Patent Publication 2013-195603
Patent Literature 3: International Unexamined Patent Publication 2015/170505
Patent Literature 4: U.S. Unexamined Patent Publication 2010/0073262
Patent Literature 5: International Unexamined Patent Publication 2017/065225
Patent Literature 6: Japanese Unexamined Patent Publication 2018-072591

As for a conventional light beam multiplexing light source device where semiconductor lasers and an optical waveguide-type multiplexer are combined, a light beam multiplexing light source device for multiplexing laser beams of three primary colors is formed of optical waveguides made of a core and a clad where semiconductor lasers for generating red, blue and green light beams, for example, are installed at the entrance ends of the optical waveguides that correspond to the respective colors. Here, the light beams propagate through the cores of the optical waveguides, and a multiplexed light beam is emitted from the emission end of the optical multiplexer.

Efforts have been made to develop the conventional light beam multiplexing light source devices of this type in order to maximize the efficiency in the transmission from the semiconductor laser output to the light source device output. It is possible to make the efficiency in the transmission 90% or greater by improving the efficiency in the coupling between the semiconductor lasers and the optical waveguides of the multiplexer and the efficiency in the optical multiplexing. In this case, conventional semiconductor lasers can be operated with the rated output so as to make the multiplexer output several mW.

In a retina scanning-type display to which a multiplexing light source device is mainly applied, the optical power for the final entrance into a pupil of a viewer is approximately 10 μW. In the case where the semiconductor lasers are driven with a small current in order to make the optical power for the entrance into a pupil smaller, such a problem arises that the optical dynamic range shrinks due to a spontaneous light component emission.

As another method for lowering the optical power, there is a technique for inserting an optical attenuator element such as a light absorber/reflector or an optical axis shift coupling unit into the optical path. In this case, an additional element for causing a light attenuation is necessary, and moreover, there is a concern that the reliability may be lowered due to the change in the characteristics of the additional optical element or the displacement in the alignment.

An object of the present invention is to provide an optical waveguide-type optical multiplexer having an optical waveguide for light input, an optical waveguide on the light emission side and an optical multiplexing unit where the intensity of a light beam emitted from a light source can be attenuated to a desired value without installing an additional optical attenuator element.

### SUMMARY

According to one aspect of the invention, an optical waveguide-type optical multiplexer is provided with: a plurality of optical waveguides for light input into which light having different wavelengths enters from a plurality of light sources; an optical multiplexer unit for distributing/multiplexing light that has propagated through the optical waveguides for light input; and a plurality of optical waveguides on the light emission side for emitting light that has been distributed/multiplexed in the optical multiplexer unit, wherein one of the optical waveguides on the light emission side excluding an optical waveguide on the light emission side in which the greatest output light power can be gained for each wavelength from among the optical waveguides on the light emission side in the case where the plurality of light sources is driven is used as an optical waveguide for light emission, and the optical waveguides on the light emission side excluding the optical waveguides for light emission are not linear up to the emission end.

According to another aspect of the invention, an optical waveguide-type optical multiplexer is provided with: a plurality of optical waveguides for light input into which light having different wavelengths enters from three or more light sources; an optical multiplexer unit for distributing/multiplexing light that has propagated through the optical waveguides for light input; and a plurality of optical waveguides on the light emission side for emitting light that has been distributed/multiplexed in the optical multiplexer unit, wherein an optical waveguide on the light emission side where the maximum output light power can be gained for at least one wavelength from among the optical waveguides on the light emission side excluding an optical waveguide on the light emission side where the greatest multiplexed output light power can be gained in the case where the three or more light sources are driven with the same output is used as an optical waveguide for light emission, and the optical waveguides on the light emission side excluding the optical waveguide for light emission are not linear up to the emission end.

According to still another aspect of the invention, an optical waveguide-type multiplexing light source optical device is provided with: a plurality of light sources; a plurality of optical waveguides for light input into which light enters from the plurality of light sources; an optical multiplexer unit for distributing/multiplexing light that has propagated through the optical waveguides for light input; and a plurality of optical waveguides on the light emission side for emitting light that has been distributed/multiplexed in the optical multiplexer unit, wherein one of the optical waveguides on the light emission side excluding an optical waveguide on the light emission side in which the greatest output light power can be gained for each wavelength from among the optical waveguides on the light emission side in the case where the plurality of light sources is driven is used as an optical waveguide for light emission, and the optical waveguide-type multiplexing light source optical device further comprises an optical element that can be optically coupled with a signal light from the optical waveguide for light emission.

According to yet another aspect of the invention, an optical waveguide-type multiplexing light source optical device is provided with: three or more light sources for emitting light with different wavelengths; a plurality of optical waveguides for light input into which light having different wavelengths enters from the three or more light sources; an optical multiplexer unit for distributing/multiplexing light that has propagated through the optical waveguides for light input; and a plurality of optical waveguides on the light emission side for emitting light that has been distributed/multiplexed in the optical multiplexer unit, wherein an optical waveguide on the light emission side where the maximum output light power can be gained for at least one wavelength from among the optical waveguides on the light emission side excluding an optical waveguide on the light emission side where the greatest multiplexed output light power can be gained in the case where the three or more light sources are driven with the same output is used as an optical waveguide for light emission, and the optical waveguide-type multiplexing light source optical device further comprises an optical element that can be optically coupled with a signal light from the optical waveguide for light emission.

According to still yet another aspect of the invention, an image projection devise is provided with: the optical waveguide-type multiplexing light source optical device that includes the above-described optical element for scanning with light; and an image formation unit for projecting onto a projection surface an image scanned with light that has been multiplexed by the optical element for scanning with light in the optical waveguide-type multiplexing light source optical device.

In accordance with one aspect of an optical waveguide-type optical multiplexer having an optical waveguide for light input, an optical waveguide on the light emission side and an optical multiplexing unit, it becomes possible for the intensity of a light beam emitted from a light source to be attenuated to a desired value without installing an additional optical attenuator element. A compact retina scanning-type display with high reliability can be gained by using such an optical waveguide-type optical multiplexer.

### BRIEF DESCRIPTION OF DRAWINGS

FIG. 1 is a schematic plan diagram illustrating the optical waveguide-type optical multiplexer according to an embodiment of the present invention;

FIGS. 2A, 2B and 2C are diagrams illustrating the structures of optical coupling portions in the embodiment of the present invention;

FIGS. 3A and 3B are schematic diagrams illustrating the configuration of the optical waveguide-type optical multiplexer in Example 1 of the present invention;

FIGS. 4A and 4B are schematic diagrams illustrating the configuration of the optical waveguide-type optical multiplexer in Example 3 of the present invention;

FIGS. 5A and 5B are schematic diagrams illustrating the configuration of the optical waveguide-type optical multiplexer in Example 4 of the present invention;

FIG. 6 is a schematic diagram illustrating the configuration of the optical waveguide-type optical multiplexer in Example 6 of the present invention;

FIG. 7 is a schematic diagram illustrating the configuration of the optical waveguide-type optical multiplexer in Example 7 of the present invention;

FIGS. 8A and 8B are schematic diagrams illustrating the configuration of the optical waveguide-type optical multiplexer in Example 8 of the present invention;

FIGS. 9A and 9B are schematic diagrams illustrating the configuration of the optical waveguide-type optical multiplexer in Example 9 of the present invention;

FIGS. 10A and 10B are schematic diagrams illustrating the configuration of the optical waveguide-type optical multiplexer in Example 10 of the present invention;

FIG. 11 is a schematic diagram illustrating the configuration of the optical waveguide-type optical multiplexer in Example 11 of the present invention;

FIGS. 12A and 12B are schematic diagrams illustrating the configuration of the optical waveguide-type optical multiplexer in Example 12 of the present invention;

FIGS. 13A and 13B are schematic diagrams illustrating the configuration of the optical waveguide-type optical multiplexer in Example 13 of the present invention;

FIG. 14 is a schematic diagram illustrating the configuration of the light source module in Example 14 of the present invention;

FIG. 15 is a schematic diagram illustrating the configuration of the optical waveguide-type multiplexing light source optical device in Example 15 of the present invention;

FIG. 16 is a schematic diagram illustrating the configuration of the optical waveguide-type multiplexing light source optical device in Example 16 of the present invention;

FIG. 17 is a schematic diagram illustrating the configuration of the optical waveguide-type multiplexing light source optical device in Example 17 of the present invention;

FIG. 18 is a schematic diagram illustrating the configuration of the optical waveguide-type multiplexing light source optical device in Example 18 of the present invention;

FIG. 19 is a schematic diagram illustrating the configuration of the optical waveguide-type multiplexing light source optical device in Example 19 of the present invention;

FIG. 20 is a schematic diagram illustrating the configuration of the optical waveguide-type multiplexing light source optical device in Example 20 of the present invention;

FIG. 21 is a schematic diagram illustrating the configuration of the optical waveguide-type multiplexing light source optical device in Example 21 of the present invention;

FIG. 22 is a schematic diagram illustrating the configuration of the optical waveguide-type multiplexing light source optical device in Example 22 of the present invention;

FIG. 23 is a schematic diagram illustrating the configuration of the optical waveguide-type multiplexing light source optical device in Example 23 of the present invention;

FIG. 24 is a schematic diagram illustrating the configuration of the optical waveguide-type multiplexing light source optical device in Example 24 of the present invention;

FIGS. 25A and 25B are schematic diagrams illustrating the configuration of the optical waveguide-type multiplexing light source optical device in Example 26 of the present invention;

FIGS. 26A and 26B are schematic diagrams illustrating the configuration of the optical waveguide-type multiplexing light source optical device in Example 27 of the present invention;

FIGS. 27A and 27B are schematic diagrams illustrating the configuration of the optical waveguide-type multiplexing light source optical device in Example 28 of the present invention;

FIG. 28 is a schematic plan diagram illustrating a conventional optical waveguide-type optical multiplexer made by the present inventors;

FIG. 29 is a schematic perspective diagram illustrating an example of a conventional two-dimensional optical scanning device; and

FIG. 30 is a schematic perspective diagram illustrating a conventional image formation device.

### DESCRIPTION OF EMBODIMENTS

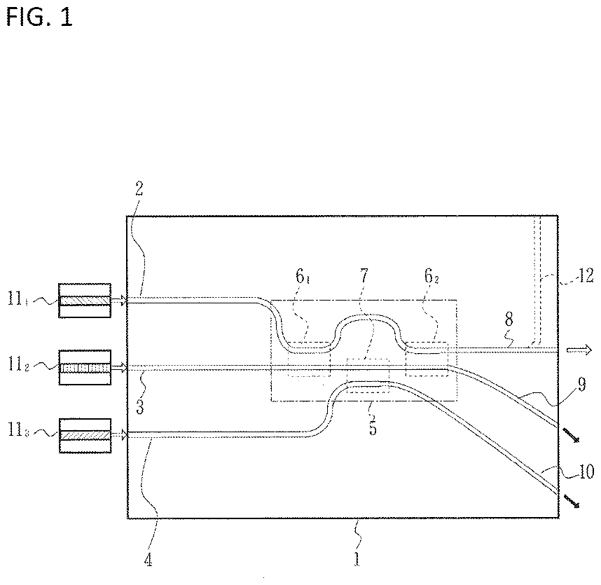

Here, an example of the optical waveguide-type optical multiplexer according to an embodiment of the present invention is described in reference to FIG. 1. FIG. 1 is a schematic plan diagram illustrating the optical waveguide-type optical multiplexer according to one embodiment of the present invention. Here, the optical waveguide-type optical multiplexer is illustrated as a light source module by adding light sources 11₁ through 11₃. As illustrated in FIG. 1, the optical waveguide-type optical multiplexer according to an embodiment of the present invention has a plurality of optical waveguides 2 through 4 for allowing light having different wavelengths from a plurality of light sources 11₁ through 11₃ to enter, an optical multiplexer unit 5 for distributing/multiplexing light that has propagated through the optical waveguides 2 through 4 for light input, and a plurality of optical waveguides 8 through 10 on the light emission side for light emission that has been distributed/multiplexed in the optical multiplexer unit 5. In this case where a plurality of light sources 11₁ through 11₃ is driven, one of the optical waveguides 8 or 10 on the light emission side other than the optical waveguide 9 on the light emission side where the greatest output light power can be gained for each of all the wavelengths within the optical waveguides 8 through 10 on the light emission side is used as an optical waveguide for light emission. In FIG. 1, the optical waveguide 8 on the light emission side is used as the optical waveguide for light emission. The optical waveguide for light emission is not linear up to the emission end and is preferably an optical waveguide in linear form at least in a region other than the proximity to the emission end. The optical waveguides 9 and 10 on the light emission side other than the optical waveguide for light emission are preferably inclined relative to the propagation axis line of the optical multiplexer unit 5.

Here, the attenuation coefficient for adjusting the output light power is set depending on the lengths of the directional coupler that forms the respective optical coupling parts 6₁, 6₂ and 7 and the gaps between the optical waveguides that form the directional coupler. In the optical waveguide (8) on the light emission side that becomes the optical waveguide for light emission, at least the optical waveguide in linear form in the region other than the proximity to the emission end agrees with the propagation axis line of the optical multiplexer unit 5 by +/−10° or less. Here, the propagation axis line means an axis line that agrees with the direction in which light progresses as a whole through the inside of the optical waveguide that forms the multiplexer unit 5 and that approximately agrees with the center axis of the optical multiplexer unit 5. In addition, the size of the output power for each wavelength is proportional to the ratio of the quantity of light that has entered into the optical waveguides 2 through 4 for light input to the quantity of light (light power) emitted from the optical waveguides 8 through 10 on the light emission side.

In addition, a modification thereof has a plurality of optical waveguides 2 through 4 for allowing light having different wavelengths to enter from three or more light sources 11₁ through 11₃, the optical multiplexer unit 5 for distributing/multiplexing light that has propagated through the optical waveguides 2 through 4 for light input, and a plurality of optical waveguides 8 through 10 on the light emission side for emitting light that has been distributed/multiplexed in the optical multiplexer unit 5. In the case where the light sources 11₁ through 11₃ are driven with the same output, the optical waveguide on the light emission side other than the optical waveguide on the light emission side where the greatest multiplexed output light power can be gained from among the optical waveguides 8 through 10 on the light emission side and where the greatest output light power can be gained for at least one wavelength is used as an optical waveguide for light emission. The optical waveguide for light emission is not linear up to the emission end and is preferably an optical waveguide in linear form in at least a region other than the proximity to the emission end. The optical waveguides on the light emission side other than the optical waveguide for light emission is preferably inclined relative to the propagation axis line of the optical multiplexer unit 5. Here, the lengths of the directional couplers that form the respective optical coupling parts 6₁, 6₂ and 7 and the gap between the optical waveguides that form the directional coupler are set so as to be different from those in the embodiment.

In this case, it is desirable for the light attenuation from the input power for the optical waveguides 2 through 4 for light input to the output power from the optical waveguide (8) for light emission to be set to a value in a range from 5 dB to 40 dB. That is to say, depending on the rated output P_{Id} (=1 mW to 10 mW) of the semiconductor laser, the loss of coupling α_{cp} with an optical waveguide and the loss of transmittance α_{sys} through the display optical system, the value required for the light attenuation αₘₚₓ (=10 log (P_{Id}/P_{dp})−α_{cp}−α_{sys}) from the entrance power of light that has entered into the optical waveguides 2 through 4 for light input to the multiplexed light output power outputted from the optical waveguide (8) for light emission is in a range from 5 dB to 40 dB, more preferably from 10 dB to 30 dB. Here, P_{dp} is a so-called display light power and approximately 1 μW to 10 μW. In addition, the loss (α_{cp}+α_{sys}) becomes 15 dB or less. When the attenuation is lower than 5 dB, the display light power becomes a value that exceeds a required range P_{dp} even in the case where P_{Id} is the minimum of 1 mW and the loss (α_{cp}+α_{sys}) is the maximum of 15 dB. Meanwhile, when the attenuation is greater than 40 dB, the required quantity of light cannot be gained.

The optical waveguide on the light emission side that becomes the optical waveguide for light emission (8 in the case in FIG. 1) is an optical waveguide in linear form at least in a region other than the proximity to the emission end; however, it may be inclined in proximity to the emission end at an angle of 85° to 95° relative to the optical waveguide 8 in linear form as the bent portion 12 denoted with a broken line in the figure. When a bent portion 12 is provided as described above, stray light that has leaked out from the optical coupling parts 6₁, 6₂ and 7 in the optical multiplexer unit 5 can be surely prevented from overlapping with multiplexed light.

Here, the optical waveguides 9 and 10 on the light emission side other than the optical waveguide (8) for light emission are optical waveguides for discarding light or an optical waveguide for monitoring. The number of optical waveguides 2 through 4 for light input is arbitrary (three in the case in FIG. 1), and may be two or four or more. In the case of four or more, yellow light or infrared rays may be added in addition to the three primary colors. The number of optical waveguides 8 through 10 on the light emission side may be the same as the number of optical waveguides 2 through 4 for light input or may be fewer than the number of optical waveguides 2 through 4 for light input.

Here, the optical multiplexer unit 5 is typically an optical multiplexing unit for multiplexing at least three primary colors, red light, blue light and green light. Here, the arrangement of the light sources 11₁ through 11₃ and the order in which light couples are arbitrary.

Alternatively, the direction in which light is guided through a plurality of optical waveguides 2 through 4 for light input may be inclined at an angle of 85° to 95° in proximity to the input end relative to the optical waveguide (8) in linear form. The arrangement in this manner can make the size of the optical waveguide-type optical multiplexer smaller in the direction of the length, and at the same time can reduce the effects of stray light from the light sources.

In this case, the plurality of light sources 11₁ through 11₃ may be arranged along one side of the substrate 1 so that the direction in which light is guided in proximity to the input ends of the plurality of optical waveguides 2 through 4 for light input forms an angle of 85° to 95° with the optical axis of the optical waveguide (8) in linear form. Alternatively, at least one (11₁) from among the plurality of light sources 11₁ through 11₃ may be arranged along a first side of the substrate, and the remaining light sources (11₂ and 11₃) may be arranged along a second side that face the first side so that the direction in which light is guided in proximity to the input ends of the plurality of optical waveguides 2 through 4 for light input forms an angle of 85° to 95° with the optical axis of the optical waveguide (8) in linear form.

In the case where an optical waveguide-type multiplexing light source optical device is formed, a plurality of light sources is provided to a waveguide-type optical coupler or a modification thereof that are depicted in the embodiment, and at the same time, an optical element may be optically coupled with a signal light from the optical waveguide (8) for light emission that becomes an optical waveguide for light emission.

In this case, typical examples of the optical element include a condenser lens, an optical fiber, an optical element for scanning with light and any combinations of these. Here, the light sources 11₁ through 11₃ are typically semiconductor lasers and may be light emitting diodes (LEDs) or light sources via optical fibers or optical fibers with a lensed end. In the case where optical fibers or optical fibers with a lensed end are used, a liquid laser or a solid laser may be used as the light source thereof. In addition, in the case of a light source other than an optical fiber with a lensed end, condenser lenses may be provided between the light sources 11₁ through 11₃ and the optical waveguides 2 through 4 for light input.

The emission ends of the optical waveguides (9 and 10) on the light emission side other than the optical waveguide for light emission may be arranged along a first side of the substrate 1, and the emission end of the optical waveguide (8) that becomes the optical waveguide for light emission may be arranged along a second side that crosses the first side.

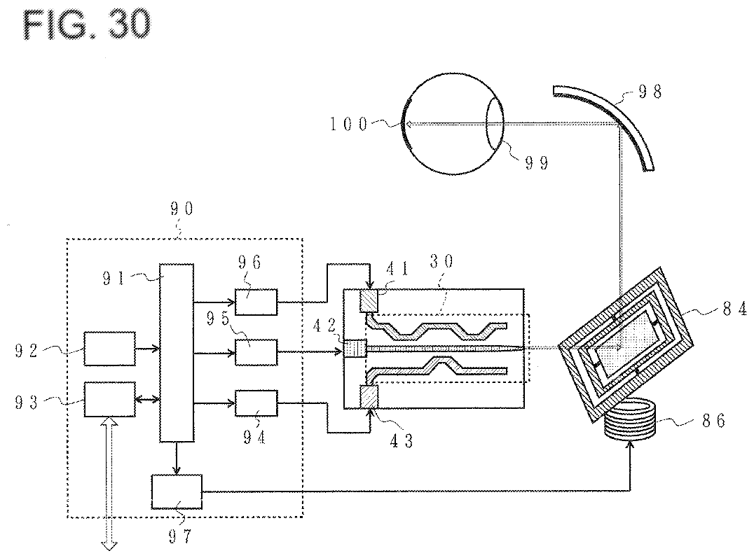

In order to form an image projection device, as illustrated in FIG. 30, an optical element (84) for scanning with light as described above, a two-dimensional scanning control unit for two-dimensional scanning with emission light emitted from a light source by applying a two-dimensional light scanning signal to an electromagnetic coil 86, and an image formation unit for projecting onto a projection surface an image scanned with the emission light may be combined. The image projection device is typically an eyeglass-type retina scanning display (see Patent Literature 6).

Here, the substrate 1 may be any from among an Si substrate, a glass substrate, a sapphire substrate, a metal substrate, a plastic substrate and the like. As for the material for the lower clad layer, the core layer and the upper clad layer, an SiO₂ glass-based material can be used, and in addition, a transparent plastic such as an acrylic resin and other transparent materials may be used. In the case of wavelengths other than RGB, a semiconductor material such as an Si or a GaN-based material may be used for the clad layer and the core layer.

As for the structure of each optical waveguide, each core in the core layer may be covered with a common upper clad layer, each core in the core layer may by covered with an individual upper clad in the upper clad layer, or each core in the core layer may be covered with an individual lower clad in the lower clad layer and an individual upper clad in the upper clad layer.

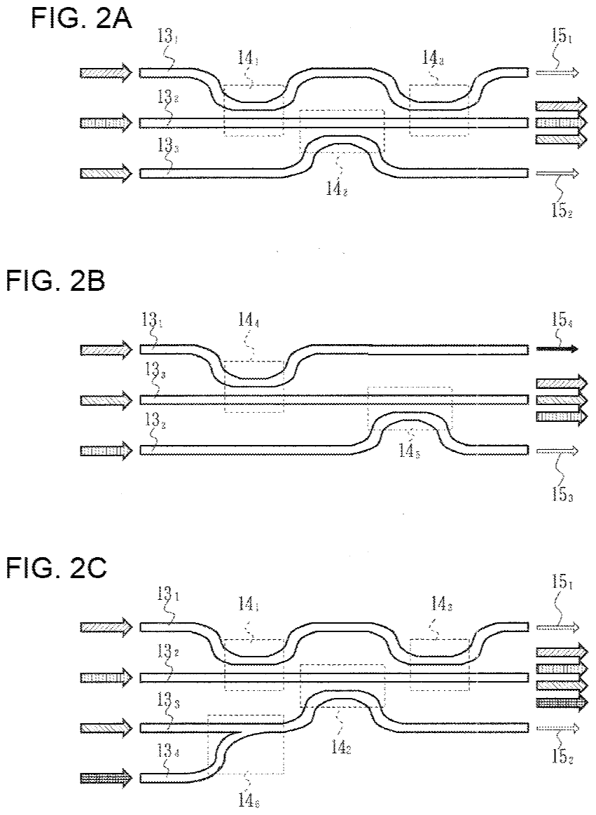

The structure of the optical multiplexer unit 5 is arbitrary, and an example of the optical multiplexer end is described in reference to FIGS. 2A through 2C. FIGS. 2A through 2C are diagrams illustrating the structure of the optical multiplexer unit according to an embodiment of the present invention. In FIG. 2A, the optical multiplexer unit has an optical waveguide 13₂ in linear form for guiding green light, an optical waveguide 13₁ for guiding blue light that optically couples with the optical waveguide for guiding green light through two optical coupling parts 14₁ and 14₃, and an optical waveguide 13₃ for guiding red light that optically couples with the optical waveguide 13₂ for guiding green light through an optical coupling part 142 between the two optical coupling parts 14₁ and 14₃. Here, the output end of the optical waveguide 13₂ for guiding green light is connected to the optical waveguide on the light emission side that can gain the greatest multiplexed output light power from among the optical waveguides on the light emission side, and a signal light 15₁ or 15₂ is outputted from any of the other optical waveguides on the light emission side. Here, in FIG. 2A, the optical waveguide 13₂ for guiding green light is an optical waveguide in linear form; however, it is not necessary to be in linear form and may be curved towards the lower side between the two optical coupling parts 14₁ and 14₃. In this case, the optical waveguide 13₃ for guiding red light may be an optical waveguide in linear form or may be an optical waveguide having a curved portion that is directed towards the curved portion provided in the optical waveguide for guiding green light.

In FIG. 2B, the optical multiplexer unit has an optical waveguide 13₃ in linear form for guiding red light having a great dispersion, an optical waveguide 13₁ for guiding blue light that optically couples with the optical waveguide 13₃ for guiding red light through an optical coupling part 144, and an optical waveguide 13₂ for guiding green light that optically couples with the optical waveguide 13₃ for guiding red light through an optical coupling part 14₅. The optical waveguide 13₃ for guiding red light is connected to the optical waveguide on the light emission side that can gain the greatest multiplexed output light power from among the optical waveguides on the light emission side. A light signal 15₃ is outputted from the optical waveguide 13₂ for guiding green light that optically couples with the optical waveguide 13₃ for guiding red light through the optical coupling part 14₅ in the rear stage, and the signal light 15₄ that has been guided through the optical waveguide 13₁ for guiding blue light is discarded. Here, in FIG. 2B, the optical waveguide 13₃ for guiding red light is an optical waveguide in linear form; however, it is not necessary to be in linear form and may be curved towards the lower side. In this case, the optical waveguide 13₂ for guiding green light may be an optical waveguide in linear form, which is optically coupled through a curved portion that is provided in the optical waveguide 13₃ for guiding red light.

FIG. 2C illustrates a case where four or more optical waveguides for light input are provided, and an optical waveguide 13₄ for guiding yellow light is coupled with the optical waveguide 13₃ for guiding red light through a Y-branched type multiplexing unit 14₆ in the optical waveguide part illustrated in FIG. 2A. In FIG. 2C, the optical waveguide 13₂ for guiding green light is an optical waveguide in linear form; however, it is not necessary to be in linear form and may be bent towards the lower side. In this case, the optical waveguide 13₃ for guiding red light may be an optical waveguide in linear form which is optically coupled through a bent portion provided in the optical waveguide 13₃ for guiding green light.

### Example 1

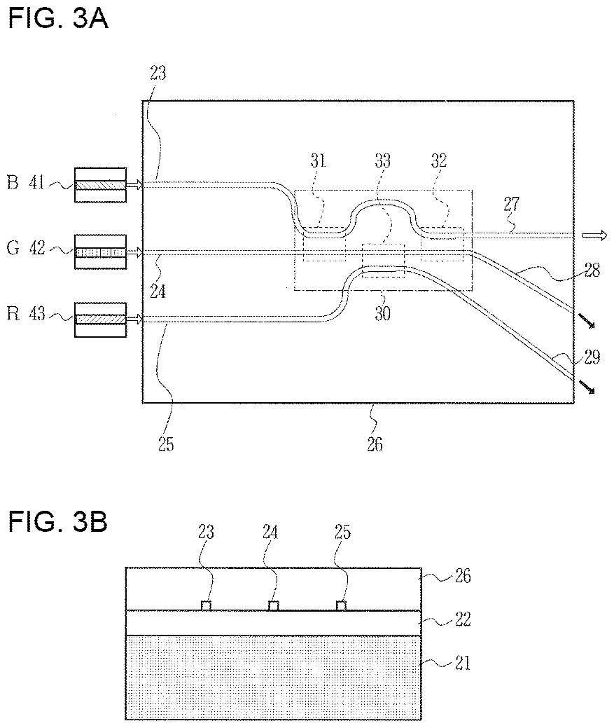

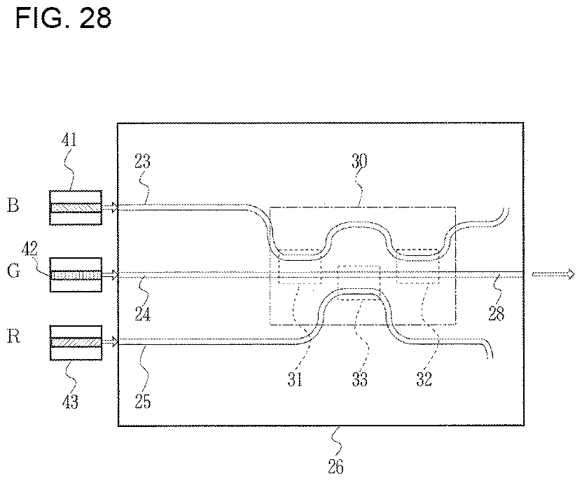

Here, the optical waveguide-type optical multiplexer in Example 1 of the present invention is described in reference to FIGS. 3A and 3B. FIGS. 3A and 3B are schematic diagrams illustrating the configuration of the optical waveguide-type optical multiplexer in Example 1 of the present invention. FIG. 3A is a schematic plan diagram, and FIG. 3B is a cross-sectional diagram on the input end side. Here, the optical waveguide-type optical multiplexer in Example 1 of the present invention is gained by modifying the optical waveguide for light emission in the conventional optical waveguide-type optical multiplexer illustrated in FIG. 28. The optical waveguide-type optical multiplexer is illustrated as a light source module by adding light sources for the purpose of easy understanding of the invention.

As illustrated in FIG. 3A, the light beam from a blue semiconductor laser chip 41 is inputted in an optical waveguide 23 for light input, the light beam from a green semiconductor laser chip 42 is inputted into an optical waveguide 24 for light input, and the light beam from a red semiconductor laser chip 43 is inputted into an optical waveguide 25 for light input.

As illustrated in FIG. 3B, each optical waveguide from among optical waveguides 23 through 25 for light input and optical waveguides 27 through 29 on the light emission side is formed of a lower clad layer, which is an SiO₂ layer 22 having a thickness of 20 μm provided on top of an Si substrate 21 having a thickness of 1 mm and a (100) surface as the main surface, a core layer having a width×a height of 2 μm×2 μm that is formed by etching Ge-doped SiO₂ glass provided on top of the SiO₂ layer 22, and an upper clad layer 26 that is made of an SiO₂ layer having a thickness of 9 μm provided on top of the core layer (the thickness on top of the SiO₂ layer becomes 11 μm). In this case, the difference in the refractive index between the core layer and the clad layer is 0.5%.

As for the size of the optical waveguide-type optical multiplexer, the length is 3 mm and the width is 3.1 mm. The length of the optical coupling part 31 is 240 μm, the length of the optical coupling part 32 is 240 μm, and the length of the optical coupling part 33 is 200 μm. The wavelength of light emitted from the blue semiconductor laser chip 41 is 450 nm, the wavelength of light emitted from the green semiconductor laser chip 42 is 520 nm, and the wavelength of light emitted from the red semiconductor laser chip 43 is 638 nm.

The blue semiconductor laser chip 41, the green semiconductor laser chip 42 and the red semiconductor laser chip 43 are mounted in such a manner that the emission areas thereof are respectively matched with the entrance areas of the optical waveguides 23 through 25 for light input in the lateral direction and in the height direction with a gap vis-a-vis the input ends of the optical waveguides 23 through 25 for light input being 10 μm. The emission ends of the optical waveguides 27 through 29 on the light emission side may be a simple plane such as a plane of cleavage, and the shape of the beams may be controlled by using a spot size converter or the like.

Here, the lengths of the directional couplers that form the optical coupling parts 31 through 33 and the gaps between the optical waveguides are controlled so that the ratio of the quantity of light emitted from the optical waveguides on the light emission side to the quantity of light that has entered into the respective optical waveguides 23 through 25 for light input becomes the following value. In the case where light with a wavelength of 638 nm enters into the optical waveguide 25 for light input, as for the ratio of the quantity of light emitted from each optical waveguide 27 through 29 on the light emission side (light power) to the quantity of light that has entered, the quantity ratio of light emitted from the optical waveguide 27 on the light emission side that becomes the optical waveguide for light emission is 4.5% (the light attenuation is 13.5 dB), the quantity ratio of light emitted from the optical waveguide 28 on the light emission side is 74%, and the quantity ratio of light emitted from the optical waveguide 29 on the light emission side is 19%.

As for the ratio of the quantity of light emitted from each optical waveguide 27 through 29 on the light emission side (light power) to the quantity of light that has entered in the case where light having a wavelength of 520 nm has entered into the optical waveguide 24 for light input, the quantity ratio of light emitted from the optical waveguide 27 on the light emission side that becomes the optical waveguide for light emission is 4% (the light attenuation is 14 dB), the quantity ratio of light emitted from the optical waveguide 28 on the light emission side is 95%, and the ratio of the quantity of light emitted from the optical waveguide 29 on the light emission side is 1%.

As for the ratio of the quantity of light emitted from each optical waveguide 27 through 29 on the light emission side (light power) to the quantity of light that has entered in the case where light having a wavelength of 450 nm has entered into the optical waveguide 23 for light input, the quantity ratio of light emitted from the optical waveguide 27 on the light emission side that becomes the optical waveguide for light emission is 21.5% (the light attenuation is 6.7 dB), the quantity ratio of light emitted from the optical waveguide 28 on the light emission side is 72.5%, and the quantity ratio of light emitted from the optical waveguide 29 on the light emission side is 4%.

The optical waveguide 27 on the light emission side from which a light attenuation of 11.4 dB on average was gained as described above was used as an optical waveguide for light emission. The optical waveguide 28 on the light emission side from which the maximum emission power is outputted and the optical waveguide 29 on the light emission side having a small emission power were used as an optical waveguide for discarding light. In Example 1 of the present invention, an optical waveguide-type optical coupler having both a light multiplexing function and a light attenuation function can be gained, and therefore, it becomes possible to attenuate the intensity of a light beam emitted from a light source to a desired value without installing an additional optical attenuator element. In addition, there is almost no light leakage from the middle of an optical waveguide and no stray light is caused in the middle on an optical multiplexer, and thus, high-quality output light was gained without being affected by stray light.

### Example 2

Next, the optical waveguide-type optical multiplexer in Example 2 of the present invention is described. Only the size of the optical multiplexing unit is different, and the basic configuration is the same as in Example 1, and therefore, the optical waveguide-type optical coupler is described in reference to FIGS. 3A and 3B. Here, in the optical waveguide-type optical multiplexer, the length of the optical coupling part 31 is 240 μm, the length of the optical coupling part 32 is 240 μm, and the length of the optical coupling part 33 is 50 μm.

As a result of the above-described setting of the size, as for the ratio of the quantity of light emitted from each optical waveguide 27 through 29 on the light emission side (light power) to the quantity of light that has entered in the case where light having a wavelength of 638 nm has entered into the optical waveguide 25 for light input, the ratio of the quantity of light emitted from the optical waveguide 27 on the light emission side that becomes the optical waveguide for light emission is 1% (the light attenuation is 20 dB), the ratio of the quantity of light emitted from the optical waveguide 28 on the light emission side is 23.5%, and the ratio of the quantity of light emitted from the optical waveguide 29 on the light emission side is 73%.

As for the ratio of the quantity of light emitted from each optical waveguide 27 through 29 on the light emission side (light power) to the quantity of light that has entered in the case where light having a wavelength of 520 nm has entered into the optical waveguide 24 for light input, the ratio of the quantity of light emitted from the optical waveguide 27 on the light emission side that becomes the optical waveguide for light emission is 4% (the light attenuation is 14 dB), the ratio of the quantity of light emitted from the optical waveguide 28 on the light emission side is 95%, and the ratio of the quantity of light emitted from the optical waveguide 29 on the light emission side is 1%.

As for the ratio of the quantity of light emitted from each optical waveguide 27 through 29 on the light emission side (light power) to the quantity of light that has entered in the case where light having a wavelength of 450 nm has entered into the optical waveguide 23 for light input, the ratio of the quantity of light emitted from the optical waveguide 27 on the light emission side that becomes the optical waveguide for light emission is 23.5% (the light attenuation is 6.3 dB), the ratio of the quantity of light emitted from the optical waveguide 28 on the light emission side is 74.5%, and the ratio of the quantity of light emitted from the optical waveguide 29 on the light emission side is 1%.

As described above, the maximum light quantity is gained for light having a wavelength 520 nm and light having a wavelength of 450 nm from the optical waveguide 28 on the light emission side at the center, and the maximum light quantity is gained for light having a wavelength of 638 nm from the optical waveguide 29 on the light emission side, which is not the optical waveguide at the center, and thus, a light attenuation of 13.4 dB on average was gained from the optical waveguide 27 on the light emission side that is the optical waveguide for light emission. In Example 2 of the present invention as well, an optical waveguide-type optical multiplexer having both a light multiplexing function and a light attenuation function can be gained, and therefore, it becomes possible to attenuate the intensity of a light beam emitted from a light source to a desired value without installing an additional optical attenuator element. In addition, there is almost no light leakage from the middle of the optical waveguide and no stray light is caused in the middle of the multiplexer, and thus, high-quality output light was gained without being affected by stray light.

### Example 3

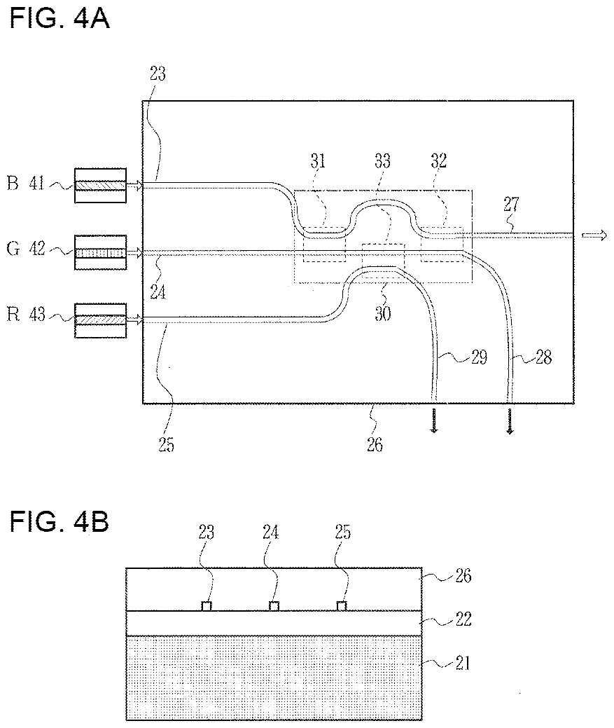

Next, the optical waveguide-type optical multiplexer in Example 3 of the present invention is described in reference to FIGS. 4A and 4B. FIGS. 4A and 4B are schematic diagrams illustrating the configuration of the optical waveguide-type optical multiplexer in Example 3 of the present invention. FIG. 4A is a schematic plan diagram, and FIG. 4B is a cross-sectional diagram on the input end side. Here, only the location of the output end of the waveguide for discarding light is different from that in the optical waveguide-type optical multiplexer in Example 1 of the present invention, and the basic configuration is the same as that of the optical waveguide-type optical multiplexer in Example 1. Here again, the optical waveguide-type optical coupler is illustrated as a light source module by adding light sources for the purpose of easy understanding of the invention.

As illustrated in FIG. 4A, the emission ends of the optical waveguides 28 and 29 on the light emission side for discarding light excluding the optical waveguide 27 on the light emission side that becomes the optical waveguide for light emission are arranged on an end surface of the substrate excluding the emission end of the optical waveguide 27 on the light emission side. Here, the end surface of the substrate is provided through the application of cleavage.

### Example 4

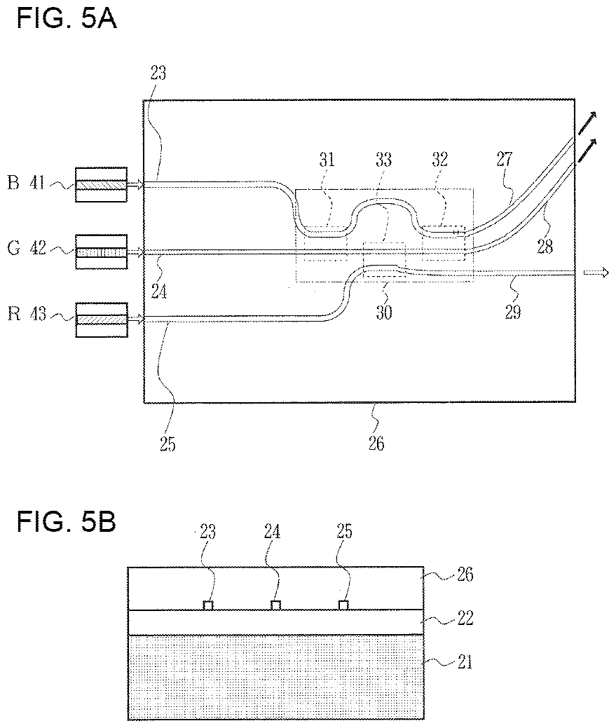

Next, the optical waveguide-type optical multiplexer in Example 4 of the present invention is described in reference to FIGS. 5A and 5B. FIGS. 5A and 5B are schematic diagrams illustrating the configuration of the optical waveguide-type optical multiplexer in Example 4 of the present invention. FIG. 5A is a schematic plan diagram, and FIG. 5B is a cross-sectional diagram on the input end side. Here, the optical waveguide-type optical multiplexer in Example 4 is the same as the optical waveguide-type optical multiplexer in Example 1, except that the optical waveguide for light emission in the optical waveguide-type optical multiplexer in Example 1 of the present invention is used as the optical waveguide 29 on the light emission side. Here again, the optical waveguide-type optical coupler is illustrated as a light source module by adding light sources for the purpose of easy understanding of the invention.

As illustrated in FIG. 5A, the optical waveguide 29 on the light emission side is used as the optical waveguide for light emission, and the optical waveguides 27 and 28 on the light emission side are used as optical waveguides for discarding light. In this case where the configurations of the optical coupling parts 31 through 33 are the same as those in Example 1, the ratio of the quantity of light outputted from the optical waveguide 29 on the light emission side is 19% for red light, 1% for green light and 4% for blue light. These ratios can be adjusted by changing the size of the optical coupling parts 31 through 33. As illustrated in FIG. 5B, each optical waveguide from among the optical waveguides 23 through 25 for light input and the waveguides 27 through 29 on the light emission side is formed of a lower clad layer, which is an SiO₂ layer 22 having a thickness of 20 μm provided on top of an Si substrate 21 having a thickness of 1 mm and a (100) surface as the main surface, a core layer having a width×a height of 2 μm×2 μm, which is formed by etching Ge-doped SiO₂ glass provided on top of the SiO₂ layer 22, and an upper clad layer 26 made of an SiO₂ layer having a thickness of 9 μm provided on top of the core layer (the thickness on top of the SiO₂ layer 22 becomes 11 μm). In this case, the difference in the refractive index between the core layer and the clad layer is 0.5%.

### Example 5

Next, the optical waveguide-type optical multiplexer in Example 5 of the present invention is described in reference to FIGS. 5A and 5B because the basic structure thereof is the same as that in Example 4 illustrated in FIGS. 5A and 5B. As illustrated in FIG. 5A, the light beam from a blue semiconductor laser chip 41 is inputted into the optical waveguide 23 for light input, the light beam from a green semiconductor laser chip 42 is inputted into the optical waveguide 24 for light input, and the light beam from a red semiconductor laser chip 43 is inputted into the optical waveguide 25 for light input. As for the size of the optical waveguide-type optical multiplexer, the length is 3 mm and the width is 3.1 mm. The length of the optical coupling part 31 is 240 μm, the length of the optical coupling part 32 is 240 μm, and the length of the optical coupling part 33 is 60 μm. The wavelength of light emitted from the blue semiconductor laser chip 41 is 450 nm, the wavelength of light emitted from the green semiconductor laser chip 42 is 520 nm, and the wavelength of light emitted from the red semiconductor laser chip 43 is 638 nm.

The blue semiconductor laser chip 41 and the green semiconductor laser chip 42 are mounted so as to respectively match the entrance areas of the optical waveguides 23 and 24 for light input in the lateral direction and in the height direction with a gap vis-a-vis the entrance ends of the optical waveguides 23 and 24 for light input being 10 μm. Meanwhile, the red semiconductor laser chip 43 is mounted so as to match the emission area in the lateral direction with the gap vis-a-vis the entrance end of the optical waveguide 25 for light input being 10 μm; however, the red semiconductor laser chip 43 is slightly shifted from the entrance end of the optical waveguide 25 for light input in the height direction. The emission ends of the optical waveguides 27 through 29 on the light emission side may be a simple plane such as a plane of cleavage; however, the shape of the beams may be controlled by using a spot size converter or the like.

Here, the lengths of the directional couplers that form the optical coupling parts 31 through 33 and the gaps between the optical waveguides are controlled so that the ratio of the quantity of light emitted from the optical waveguides 27 through 29 on the light emission side to the quantity of light that has entered into the respective optical waveguides 23 through 25 for light input becomes the following value. In the case where light with a wavelength of 638 nm enters into the optical waveguide 25 for light input, as for the ratio of the quantity of light emitted from each optical waveguide 27 through 29 on the light emission side (light power) to the quantity of light that has entered, the quantity ratio of light emitted from the optical waveguide 27 on the light emission side that becomes the optical waveguide for light emission is 2%, the quantity ratio of light emitted from the optical waveguide 28 on the light emission side is 42.5%, and the quantity ratio of light emitted from the optical waveguide 29 on the light emission side is 52%.

As for the ratio of the quantity of light emitted from each optical waveguide 27 through 29 on the light emission side (light power) to the quantity of light that has entered in the case where light having a wavelength of 520 nm has entered into the optical waveguide 24 for light input, the quantity ratio of light emitted from the optical waveguide 27 on the light emission side that becomes the optical waveguide for light emission is 3%, the quantity ratio of light emitted from the optical waveguide 28 on the light emission side is 94%, and the ratio of the quantity of light emitted from the optical waveguide 29 on the light emission side is 0.5%.

As for the ratio of the quantity of light emitted from each optical waveguide 27 through 29 on the light emission side (light power) to the quantity of light that has entered in the case where light having a wavelength of 450 nm has entered into the optical waveguide 23 for light input, the quantity ratio of light emitted from the optical waveguide 27 on the light emission side that becomes the optical waveguide for light emission is 22.5%, the quantity ratio of light emitted from the optical waveguide 28 on the light emission side is 74%, and the quantity ratio of light emitted from the optical waveguide 29 on the light emission side is 1%.

The characteristics of the optical waveguide-type optical multiplexer were gained as described above; however, in the case where the blue semiconductor laser chip 41, the green semiconductor laser chip 42 and the red semiconductor laser chip 43 are operated with the same output, the following results were gained concerning the output light power from the respective optical waveguides 27, 28 and 29 on the light emission side due to a shift in the height direction between the emission area of the red semiconductor laser chip 43 and the entrance end of the optical waveguide 25 for light input. That is to say, for light having a wavelength of 638 nm from the red semiconductor laser chip 43, the quantity of light emitted from the optical waveguide 27 on the light emission side (light power) was 0.02 mW, the quantity of light emitted from the optical waveguide 28 on the light emission side (light power) was 0.4 mW, and the quantity of light emitted from the optical waveguide 29 on the light emission side (light power) was 0.5 mW. For light having a wavelength of 520 nm from the blue semiconductor laser chip 42, the quantity of light emitted from the optical waveguide 27 on the light emission side (light power) was 0.3 mW, the quantity of light emitted from the optical waveguide 28 on the light emission side (light power) was 9.4 mW, and the quantity of light emitted from the optical waveguide 29 on the light emission side (light power) was 0.05 mW. For light having a wavelength of 450 nm from the blue semiconductor laser chip 41, the quantity of light emitted from the optical waveguide 27 on the light emission side (light power) was 2.25 mW, the quantity of light emitted from the optical waveguide 28 on the light emission side (light power) was 7.4 mW, and the quantity of light emitted from the optical waveguide 29 on the light emission side (light power) was 0.1 mW.

As a result, the multiplexed output light quantity emitted from the optical waveguide 27 on the light emission side (light power) was 2.57 mW, the multiplexed output light quantity emitted from the optical waveguide 28 on the light emission side (light power) was 17.2 mW, and the multiplexed output light quantity emitted from the optical waveguide 29 on the light emission side (light power) was 0.65 mW. Therefore, in the case where the three light sources, the blue semiconductor laser chip 41, the green semiconductor laser chip 42 and the red semiconductor laser chip 43, are driven with the same output, the optical waveguide 29 on the light emission side that can gain the maximum output light power at least for the wavelength of 638 nm from among the optical waveguides on the light emission side excluding the optical waveguide 28 on the light emission side that can gain the greatest multiplexed output light power was used as the optical waveguide for light emission.

In Example 5 of the present invention, an optical waveguide-type optical multiplexer having both a light multiplexing function and a light attenuation function can be gained, and therefore, it becomes possible to attenuate the intensity of a light beam emitted from a light source to a desired value without installing an additional optical attenuator element. In addition, there is almost no light leakage from the middle of the optical waveguides and no stray light is caused in the middle of the optical multiplexer, and thus, high-quality output light is gained without being affected by stray light.

### Example 6

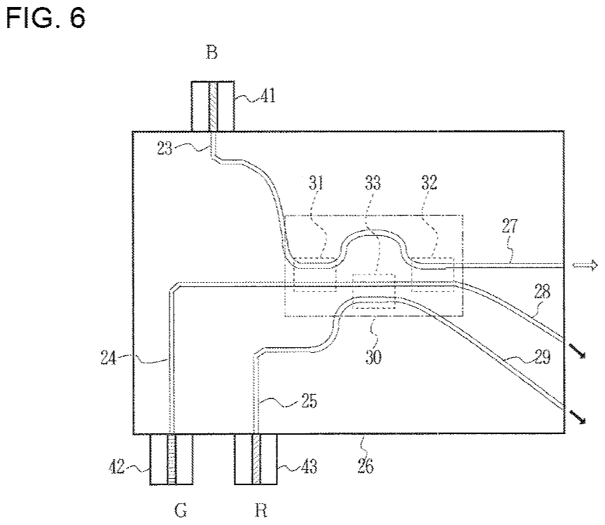

Next, the optical waveguide-type optical multiplexer in Example 6 of the present invention is described in reference to FIG. 6. FIG. 6 is a schematic diagram illustrating the configuration of the optical waveguide-type optical multiplexer in Example 6 of the present invention. Here again, the optical waveguide-type optical multiplexer is illustrated as a light source module by adding light sources for the purpose of easy understanding of the invention. As illustrated in FIG. 6, a blue semiconductor laser chip 41 is arranged along one long side of an Si substrate, and a green semiconductor laser chip 42 and a red semiconductor laser chip 43 are arranged along the other long side of the Si substrate. Here, the optical axes of the respective semiconductor lasers and the center axis of the optical waveguide 27 on the light emission side cross at an angle of 90°. Though the crossing angle is arbitrary, it may be in a range from 85° to 95°, taking an error in manufacture into consideration. As a result, the structure allows the optical waveguides 23 through 25 for light input to be bent in the middle at a right angle. In order for the optical waveguides to be bent at a right angle, a waveguide-type reflecting mirror is used; however, a bent waveguide having a small curvature radius may be used. In this case as well, the same characteristics as in Example 1 are gained.

In Example 6 of the present invention, the respective semiconductor laser chips are arranged along the long sides of an Si substrate, and therefore, in the case where a light source module is formed thereof, the length of the light source module can be made short. In addition, such a configuration can allow an optical multiplexing light source device having an extremely simple structure with both a light multiplexing function and a light attenuation function to be realized with only being slightly affected by stray light.

### Example 7

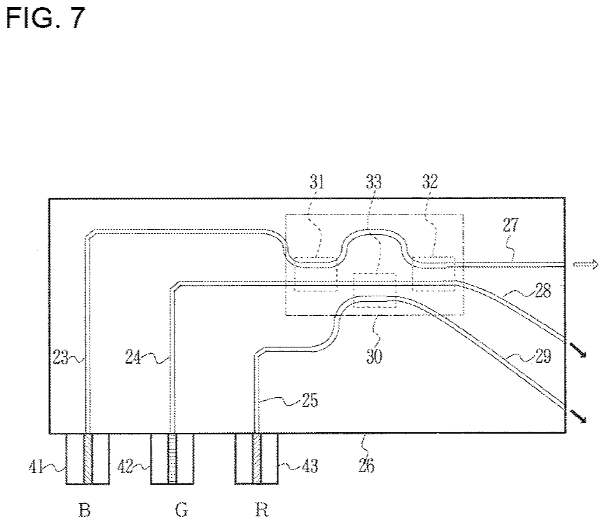

Next, the optical waveguide-type optical multiplexer in Example 7 of the present invention is described in reference to FIG. 7. FIG. 7 is a schematic diagram illustrating the configuration of the optical waveguide-type optical multiplexer in Example 7 of the present invention. Here again, the optical waveguide-type optical multiplexer is illustrated as a light source module by adding light sources for the purpose of easy understanding of the invention. As illustrated in FIG. 7, a blue semiconductor laser chip 41, a green semiconductor laser chip 42 and a red semiconductor laser chip 43 are arranged along one long side of an Si substrate. Here, the optical axes of the respective semiconductor lasers and the center axis of the optical waveguide 27 on the light emission side cross at an angle of 90°. Though the crossing angle is arbitrary, it may be in a range from 85° to 95°, taking an error in manufacture into consideration. As a result, the structure allows the optical waveguides 23 through 25 for light input to be bent in the middle at a right angle. In order for the optical waveguides to be bent at a right angle, a waveguide-type reflecting mirror is used; however, a bent waveguide having a small curvature radius may be used. In this case as well, the same characteristics as in Example 1 are gained.

In Example 7 of the present invention, the respective semiconductor laser chips are arranged along one long side of the Si substrate, and therefore, in the case where a light source module is formed, the length of the light source module can be made short, and at the same time, the width can be made short. Such a configuration can be extremely simple, and makes it possible to realize an optical multiplexing light source device having both a light multiplexing function and a light attenuation function without being affected by stray light.

### Example 8

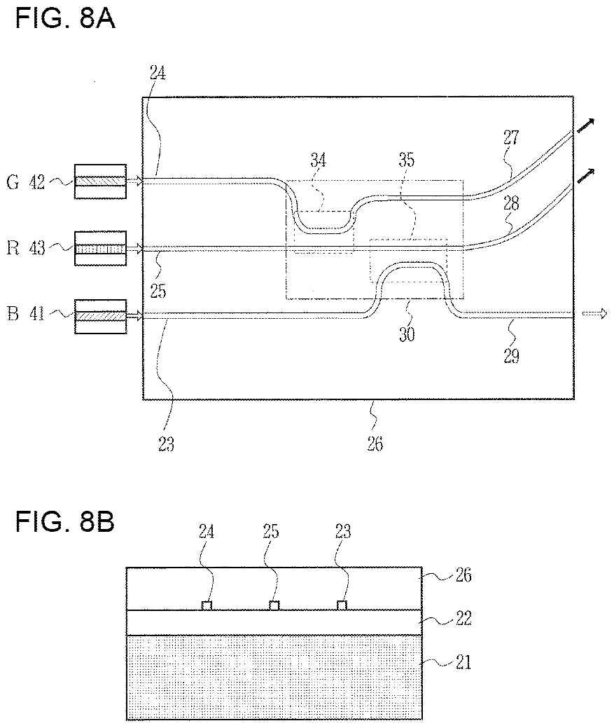

Next, the optical waveguide-type optical multiplexer in Example 8 of the present invention is described in reference to FIGS. 8A and 8B. FIGS. 8A and 8B are schematic diagrams illustrating the configuration of the optical waveguide-type optical multiplexer in Example 8 of the present invention. FIG. 8A is a schematic plan diagram, and FIG. 8B is a cross-sectional diagram on the input end side. Here again, the optical waveguide-type optical multiplexer is illustrated as a light source module by adding light sources for the purpose of easy understanding of the invention. In Example 8, the optical multiplexer unit illustrated in FIG. 2B is used as the optical multiplexer unit 30, and the remaining portions of the configuration are the same as the optical waveguide-type optical multiplexer in Example 1.

As illustrated in FIG. 8A, the optical waveguide 25 for light input that guides red light having a great dispersion is placed in the middle, the optical waveguide 24 for light input that guides green light is optically coupled with the optical waveguide 25 for light input through an optical coupling part 34, and the optical waveguide 23 for light input that guides blue light is optically coupled with the optical waveguide 25 for light input through an optical coupling part 35 located to the rear of the optical coupling part 34. The optical waveguide 25 for light input that guides red light is connected to the optical waveguide 28 on the light emission side where the greatest multiplexed output light power can be gained from among the optical waveguides on the light emission side, and a light signal is outputted from the optical waveguide 29 on the light emission side that is connected to the optical waveguide 23 for light input in a stage located to the rear of the optical connecting unit 35. In this case as well, the same characteristics as in Example 1 are gained.

### Example 9

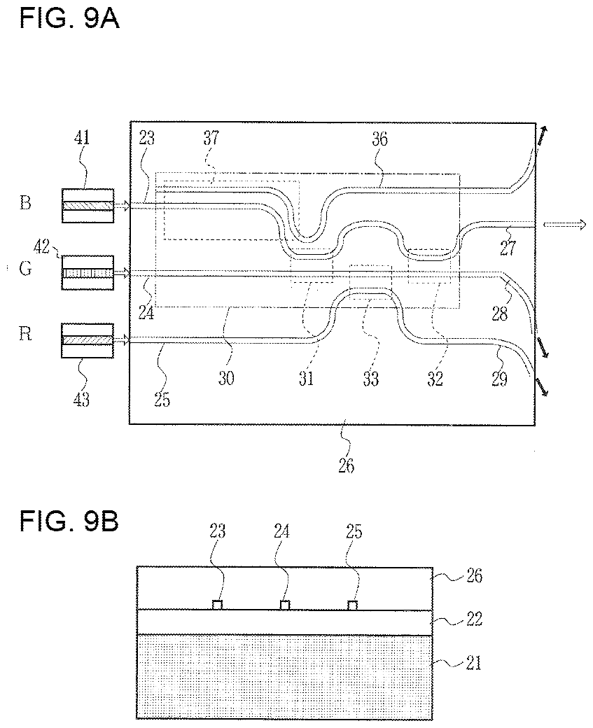

Next, the optical waveguide-type optical multiplexer in Example 9 of the present invention is described in reference to FIGS. 9A and 9B. FIGS. 9A and 9B are schematic diagrams illustrating the configuration of the optical waveguide-type optical multiplexer in Example 9 of the present invention. FIG. 9A is a schematic plan diagram, and FIG. 9B is a cross-sectional diagram on the input end side. Here again, the optical waveguide-type optical multiplexer is illustrated as a light source module by adding light sources for the purpose of easy understanding of the invention. Example 9 provides the same optical waveguide-type optical multiplexer as in Example 1, except that an optical waveguide 36 exclusively for discarding light is provided.

As illustrated in FIG. 9A, an optical waveguide 36 for exclusively discarding light is provided so as to optically couple the optical waveguide 23 for light input that guides blue light through the optical coupling part 37. In Example 9, the attenuation can be independently set in the case where the output from the blue semiconductor laser chip 41 is too large, and therefore, designing becomes easy.

### Example 10

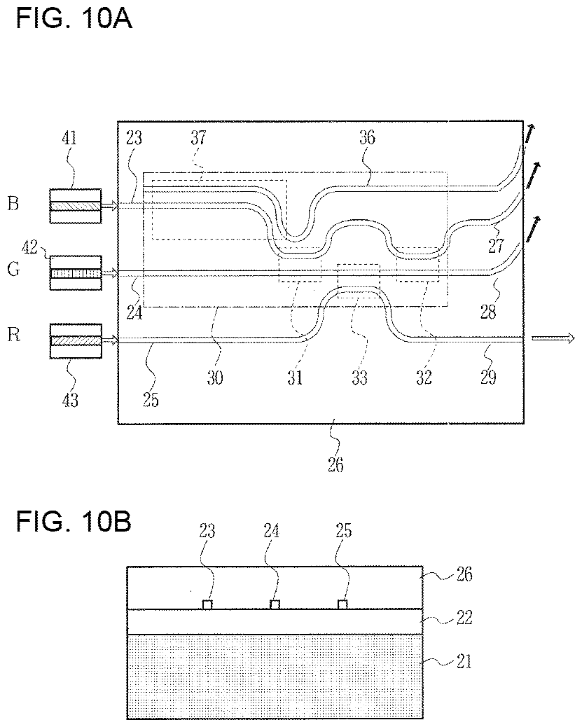

Next, the optical waveguide-type optical multiplexer in Example 10 of the present invention is described in reference to FIGS. 10A and 10B. FIGS. 10A and 10B are schematic diagrams illustrating the configuration of the optical waveguide-type optical multiplexer in Example 10 of the present invention. FIG. 10A is a schematic plan diagram, and FIG. 10B is a cross-sectional diagram on the input end side. Here again, the optical waveguide-type optical multiplexer is illustrated as a light source module by adding light sources for the purpose of easy understanding of the invention. Example 10 provides the same optical waveguide-type optical multiplexer as in Example 4, except that an optical waveguide 36 exclusively for discarding light is provided.

As illustrated in FIG. 10A, an optical waveguide 36 for exclusively discarding light is provided so as to optically couple the optical waveguide 23 for light input that guides blue light through the optical coupling part 37. In Example 10, the attenuation can be independently set in the case where the output from the blue semiconductor laser chip 41 is too large, and therefore, designing becomes easy.

### Example 11

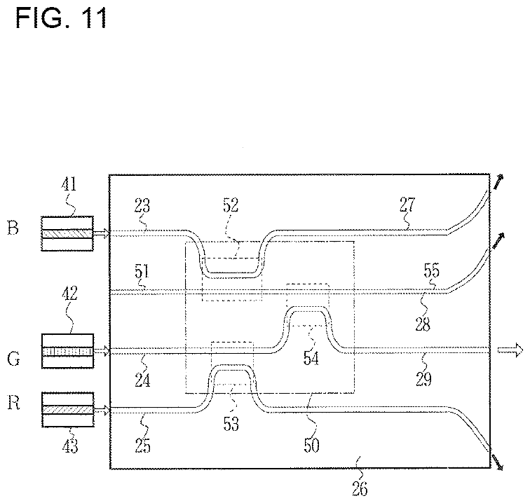

Next, the optical waveguide-type optical multiplexer in Example 11 of the present invention is described in reference to FIG. 11. FIG. 11 is a schematic diagram illustrating the configuration of the optical waveguide-type optical multiplexer in Example 11 of the present invention. Here again, the optical waveguide-type optical multiplexer is illustrated as a light source module by adding light sources for the purpose of easy understanding of the invention. As illustrated in FIG. 11, the optical multiplexing unit 50 forms an optical waveguide-type optical multiplexer together with the optical waveguide 23 through 25 and 51 for light input and the optical waveguides 27 through 29 and 55 on the light emission side. Light radiated from the blue semiconductor laser chip 41, the green semiconductor laser chip 42 and the red semiconductor laser chip 43 is not directly coupled with the optical waveguide 55 on the light emission side that becomes an optical waveguide for discarding light, and the multiplexed light output, which becomes a signal light, is outputted from the optical waveguide 28 on the light emission side that is connected to the optical coupling part 54 in the final stage.

In Example 11 of the present invention, the optical coupling ratio between the optical waveguides 23 through 25 for light input and the optical waveguide 51 for light input is adjusted so that the attenuation of the output from each semiconductor laser chip can be arbitrarily set, which makes designing easy.

### Example 12

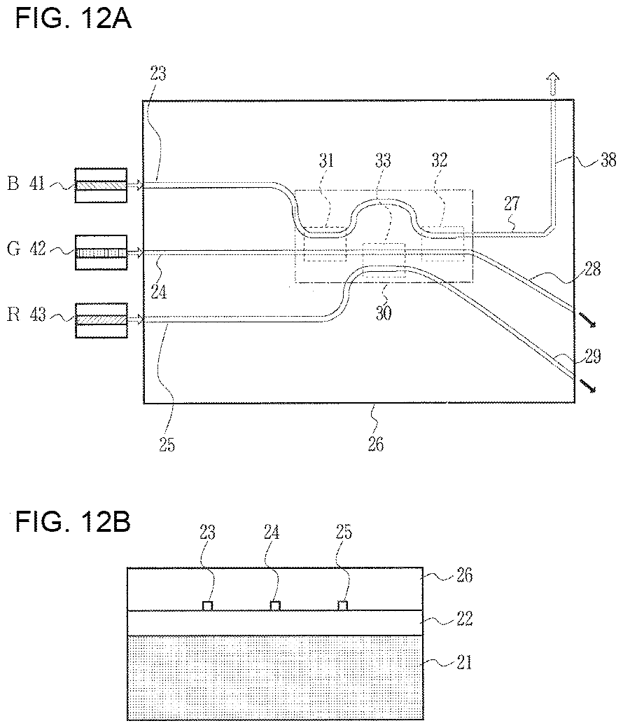

Next, the optical waveguide-type optical multiplexer in Example 12 of the present invention is described in reference to FIGS. 12A and 12B. FIGS. 12A and 12B are schematic diagrams illustrating the configuration of the optical waveguide-type optical multiplexer in Example 12 of the present invention. FIG. 12A is a schematic plan diagram, and FIG. 12B is a cross-sectional diagram on the input end side. Here again, the optical waveguide-type optical multiplexer is illustrated as a light source module by adding light sources for the purpose of easy understanding of the invention. The optical waveguide-type optical multiplexer in Example 12 can be gained by providing a bent optical waveguide 38 in proximity to the emission end of the optical waveguide 27 on the light emission side that becomes an optical waveguide for light emission, with the remaining portions of the configuration being the same as in the above-described optical multiplexer in Example 1. The bent optical waveguide 38 may be inclined at an angle of 85° to 95° relative to the optical waveguide 27 on the light emission side, which is in linear form.

In Example 12 of the present invention, a bent optical waveguide 38 is provided in proximity to the emission end of the optical waveguide 27 on the light emission side that becomes an optical waveguide for light emission, and therefore, stray light that has leaked out from the optical coupling parts 31 through 33 in the optical multiplexing unit 30 can surely be prevented from overlapping with the multiplexed light.

### Example 13

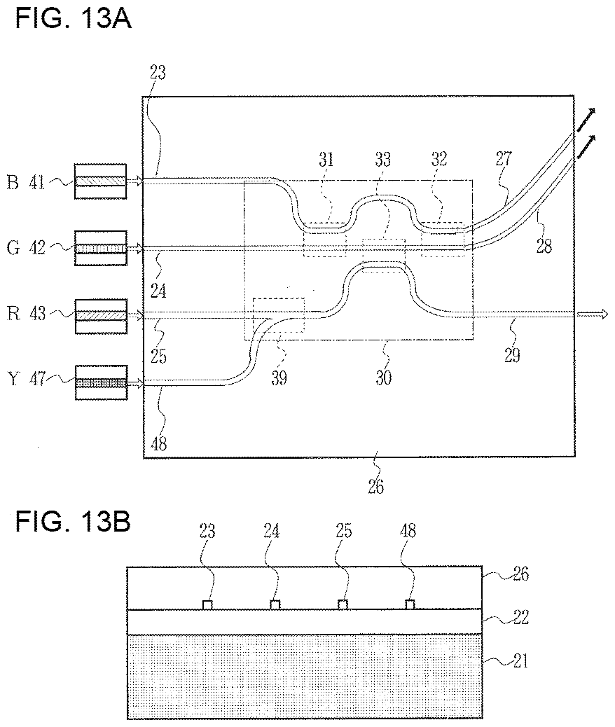

Next, the optical waveguide-type optical multiplexer in Example 13 of the present invention is described in reference to FIGS. 13A and 13B. FIGS. 13A and 13B are schematic diagrams illustrating the configuration of the optical waveguide-type optical multiplexer in Example 13 of the present invention. FIG. 13A is a schematic plan diagram, and FIG. 13B is a cross-sectional diagram on the input end side. Here again, the optical waveguide-type optical multiplexer is illustrated as a light source module by adding light sources for the purpose of easy understanding of the invention, and is gained by adding an optical waveguide on the entrance side through which yellow light propagates to an optical waveguide-type optical multiplexer as described above in Example 1.

As illustrated in FIG. 13A, a blue semiconductor laser chip 41 is arranged on the emission end surface of the optical waveguide 23 for light input, a green semiconductor laser chip 42 is arranged on the emission end surface of the optical waveguide 24 for light input, a red semiconductor laser chip 43 is arranged on the emission end surface of the optical waveguide 25 for light input, and a yellow semiconductor laser chip 47 is arranged on the emission end surface of the optical waveguide 48 for light input so that the laser beams can enter into the respective optical waveguides 23 through 25 and 48 for light input. Here, a multiplexer unit 30 is formed by adding a Y-branched type multiplexer 39.

As illustrated in FIG. 13B, each optical waveguide from among optical waveguides 23 through 25 for light input and optical waveguides 27 through 29 on the light emission side is formed of a lower clad layer, which is an SiO₂ layer 22 having a thickness of 20 μm provided on top of an Si substrate 21 having a thickness of 1 mm and a (100) surface, a core layer having a width×a height of 2 μm×2 μm that is formed by etching Ge-doped SiO₂ glass provided on top of the SiO₂ layer 22, and an upper clad layer 26 that is made of an SiO₂ layer having a thickness of 9 μm provided on top of the core layer (the thickness on top of the SiO₂ layer becomes 11 μm). In this case, the difference in the refractive index between the core layer and the clad layer is 0.5%.

As for the ratio of the quantity of light (light power) emitted from each optical waveguide 27 through 29 on the light emission side to the quantity of light that has entered in the case where light with a wavelength of 638 nm has entered into the optical waveguide 25 for light input, the ratio of the quantity of light emitted from the optical waveguide 27 on the light emission side that becomes an optical waveguide for light emission is 1.5% (the light attenuation is 18.2 dB), the ratio of quantity of light emitted from the optical waveguide 28 on the light emission side is 41%, and the ratio of quantity of light emitted from the optical waveguide 29 on the light emission side is 8%.

As for the ratio of the quantity of light (light power) emitted from each optical waveguide 27 through 29 on the light emission side to the quantity of light that has entered in the case where light with a wavelength of 520 nm has entered into the optical waveguide 24 for light input, the ratio of the quantity of light emitted from the optical waveguide 27 on the light emission side that becomes an optical waveguide for light emission is 4% (the light attenuation is 14 dB), the ratio of quantity of light emitted from the optical waveguide 28 on the light emission side is 95%, and the ratio of quantity of light emitted from the optical waveguide 29 on the light emission side is 1%.

As for the ratio of the quantity of light (light power) emitted from each optical waveguide 27 through 29 on the light emission side to the quantity of light that has entered in the case where light with a wavelength of 450 nm has entered into the optical waveguide 23 for light input, the ratio of the quantity of light emitted from the optical waveguide 27 on the light emission side that becomes an optical waveguide for light emission is 21.5% (the light attenuation is 6.7 dB), the ratio of quantity of light emitted from the optical waveguide 28 on the light emission side is 72.5%, and the ratio of quantity of light emitted from the optical waveguide 29 on the light emission side is 4%.

As for the ratio of the quantity of light (light power) emitted from each optical waveguide 27 through 29 on the light emission side to the quantity of light that has entered in the case where light with a wavelength of 570 nm has entered into the optical waveguide 48 for light input, the ratio of the quantity of light emitted from the optical waveguide 27 on the light emission side that becomes an optical waveguide for light emission is 12.5% (the light attenuation is 9 dB), the ratio of quantity of light emitted from the optical waveguide 28 on the light emission side is 7.5%, and the ratio of quantity of light emitted from the optical waveguide 29 on the light emission side is 22.5%.

From among these, the optical waveguide 25 for light input through which red light with a wavelength of 638 nm propagates and the optical waveguide 48 for light input through which yellow light with a wavelength of 570 nm propagates are connected through the Y-branched type multiplexer so as to multiplex the red and yellow light, and therefore, a loss of 3 dB is caused in the Y-branched type multiplexer. As a result, the quantity of light emitted from the optical waveguide 29 on the light emission side that becomes an optical waveguide for emitting light relative to the quantity of light that has entered into the respective optical waveguides 23 through 25 and 48 for light input becomes 16 dB for light with a wavelength of 638 nm and 20 dB for yellow light with a wavelength of 570 nm. As described above, the quantity of light emitted from the optical waveguide 27 on the light emission side that becomes an optical waveguide for light emission has a light attenuation of 16.1 dB on average relative to the light that has entered into the optical waveguides for light input.

### Example 14

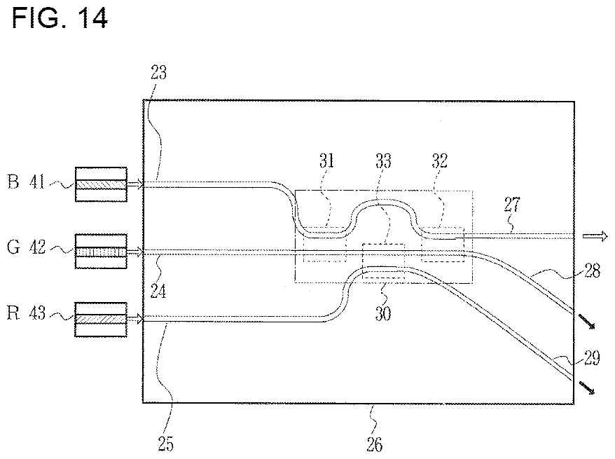

Next, the light source module in Example 14 of the present invention is described in reference to FIG. 14. FIG. 14 is a schematic diagram illustrating the configuration of the light source module in Example 14 of the present invention. The light source module in Example 14 is gained by adding a blue semiconductor laser chip 41, a green semiconductor laser chip 42 and a red semiconductor laser chip 43 that become light sources to an optical waveguide-type optical multiplexer as described above in Example 1. When a certain optical element is arranged on the emission end side of the optical waveguide 27 on the light emission side that becomes an optical waveguide for light emission, an optical waveguide-type multiplexing light source optical device is provided.

### Example 15

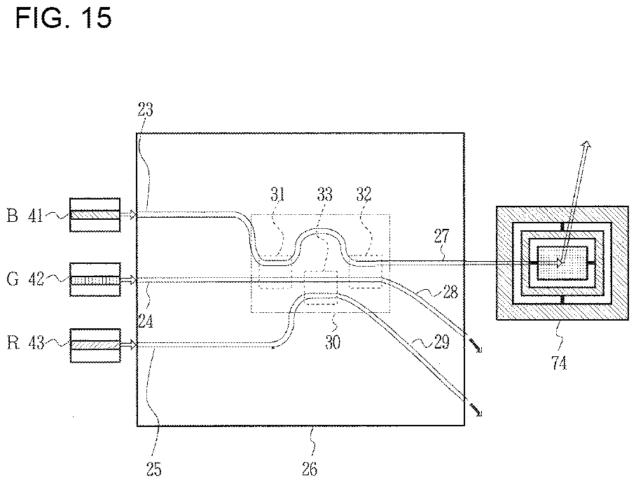

Next, the optical waveguide-type multiplexing light source optical device in Example 15 of the present invention is described in reference to FIG. 15. FIG. 15 is a schematic diagram illustrating the configuration of the optical waveguide-type multiplexing light source optical device in Example 15 of the present invention, where an MEMS mirror 74 for scanning with light is arranged as an optical element on the emission end side of the optical waveguide 27 on the light emission side that becomes an optical waveguide for light emission. The light beam emitted from the optical waveguide 27 on the light emission side that becomes an optical waveguide for light emission is reflected from the reflecting surface at the center of the MEMS mirror 74 for two-dimensional scanning with light, and thus, a reflected beam is gained. This reflected beam is used to generate an image on a screen that is installed in a place ahead.

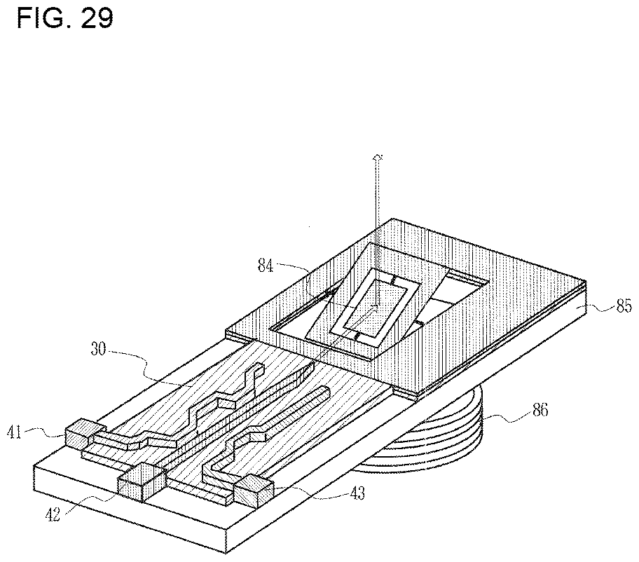

In this case, the MEMS mirror 74 for two-dimensional scanning with light is an electromagnetic drive type MEMS mirror where the reflecting surface is formed of metal glass. This metal glass is also used as the optical scanning rotation axis for rotating the mirror. The MEMS 74 for two-dimensional scanning with light is fabricated by forming an Fe—Pt thin film (thickness of 142 nm) and a metal glass film (thickness of 10 μm) in this order on top of an Si substrate having a (100) surface as the main surface and a thickness of 100 μm. The size of the mirror that becomes the reflecting unit is 500 μm×300 μm. The size of the entirety of the MEMS mirror 74 for two-dimensional scanning with light is 2.7 mm×2.5 mm, and the optical scanning rotation axis in the mirror portion agrees with the <010> direction of the Si substrate having a (100) surface as the main surface. An electromagnetic coil made of a solenoid coil as illustrated in FIG. 29 is installed beneath the optical scanning mirror unit of the MEMS mirror 74 for two-dimensional scanning with light. As for the size of the electromagnetic coil, the outer diameter is 5 mm, the height is 3 mm, and the number of windings of the wire is 800 turns. The electromagnetic coil is placed so as to make direct contact with the top of the substrate on the outer periphery of the optical scanning mirror unit in such a manner that the center portion of the electromagnetic coil agrees with the center of the mirror part that becomes the reflecting unit.

An image was projected on a screen with the reflected beams in order to evaluate the deflection angle of the light beam. As a result, the beam deflection angles of 30 degrees in the longitudinal direction and 5 degrees in the lateral direction were gained, and thus, it was possible to project an image.

### Example 16

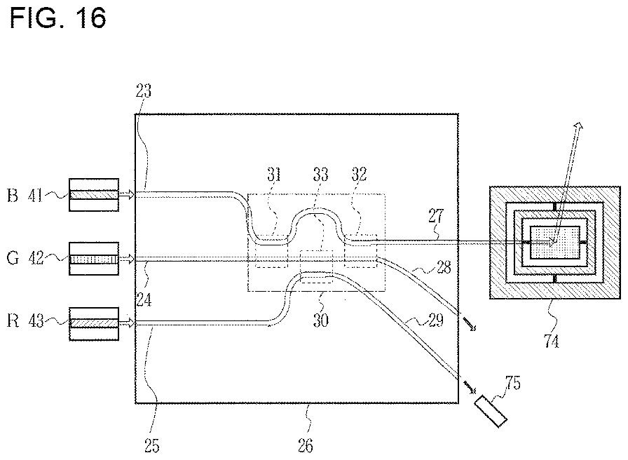

Next, the optical waveguide-type multiplexing light source optical device in Example 16 of the present invention is described in reference to FIG. 16. FIG. 16 is a schematic diagram illustrating the configuration of the optical waveguide-type multiplexing light source optical device in Example 16 of the present invention, where an MEMS mirror 74 for two-dimensional scanning with light is arranged as an optical element on the emission end side of the optical waveguide 27 on the light emission side that becomes an optical waveguide for light emission, and at the same time, a photodiode 75 for monitoring is arranged on the emission end side of the optical waveguide 29 on the light emission side.

In Example 16, the light output that is originally to be discarded is used for monitoring, and therefore, fluctuations of a signal light from the optical waveguide 27 on the light emission side that becomes an optical waveguide for light emission can be controlled.

### Example 17

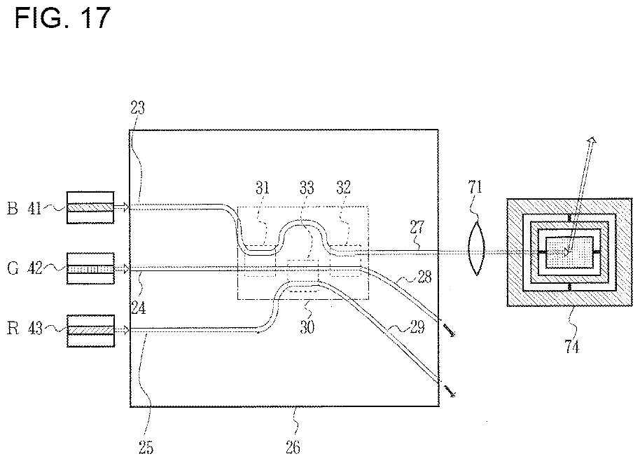

Next, the optical waveguide-type multiplexing light source optical device in Example 17 of the present invention is described in reference to FIG. 17. FIG. 17 is a schematic diagram illustrating the configuration of the optical waveguide-type multiplexing light source optical device in Example 17 of the present invention, where an MEMS mirror 74 for two-dimensional scanning with light is arrangement as an optical element on the emission end side of the optical waveguide 27 on the light emission side that becomes an optical waveguide for light emission with a condenser lens 71 in-between. Here, a biconvex lens having a focal distance of 10 mm and a diameter of 3 mm is used as the condenser lens 71. The distance between the center of the condenser lens 71 and the center of the reflecting surface of the MEMS mirror 74 for scanning with light is 10 mm. In this case as well, the same characteristics as in Example 15 are gained.

### Example 18

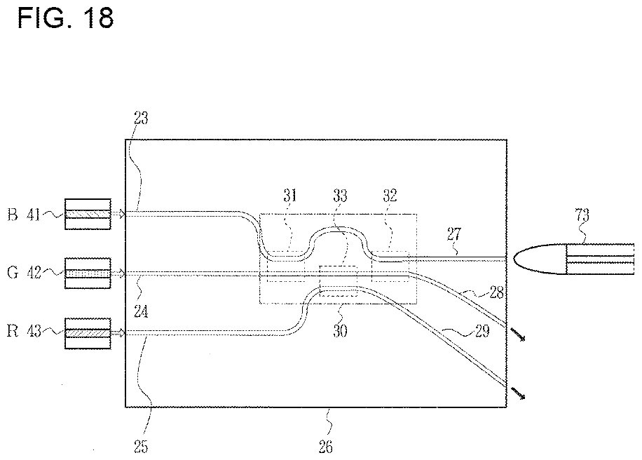

Next, the optical waveguide-type multiplexing light source optical device in Example 18 of the present invention is described in reference to FIG. 18. FIG. 18 is a schematic diagram illustrating the configuration of the optical waveguide-type multiplexing light source optical device in Example 18 of the present invention, where an optical fiber 73 with a lensed end is arranged as an optical element on the emission end side of the optical waveguide 27 on the light emission side that becomes an optical waveguide for light emission. The light beam emitted from the optical waveguide 27 on the light emission side that becomes an optical waveguide for emitting light enters into the optical fiber 73 with a lensed end, and the light that has entered into the optical fiber 73 with a lensed end is emitted from the opposite side. An image is projected onto a screen with the emitted light by using an MEMS mirror for two-dimensional scanning with light, for example. Here, an optical fiber with a lensed end having a fiber diameter of 125 μm, a beam spot diameter of 2.5 μm and a working distance of 14 μm through which light in a visible light range propagates in a single mode is used as the optical fiber 73 with a lensed end. Here, the description relates to a fiber with a lensed end; however, a regular optical fiber that was cut with an end surface can be used to provide the same results.

### Example 19

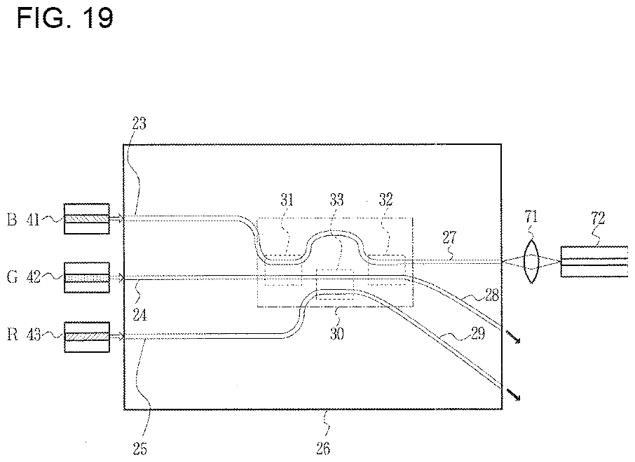

Next, the optical waveguide-type multiplexing light source optical device in Example 19 of the present invention is described in reference to FIG. 19. FIG. 19 is a schematic diagram illustrating the configuration of the optical waveguide-type multiplexing light source optical device in Example 19 of the present invention, where a condenser lens 71 and an optical fiber 72 are arranged as an optical element on the emission end side of the optical waveguide 27 on the light emission side that becomes an optical waveguide for light emission.

Here, an optical fiber having a fiber diameter of 125 μm through which light in a visible light range propagates in a single mode is used as the optical fiber 72. A biconvex lens having a focal distance of 10 mm and a diameter of 3 mm is used as the condenser lens 71. The distance between the optical waveguide 27 on the light emission side and the center of the condenser lens 71 is 20 mm, and the distance between the center of the condenser lens 71 and the entrance end of the optical fiber 72 is 20 mm.

In this case as well, the light beam that has entered via the condenser lens 71 is emitted from the opposite side of the optical fiber 72 so as to be reflected from the MEMS mirror for two-dimensional scanning with light, and thus, an image can be projected onto a screen.

### Example 20

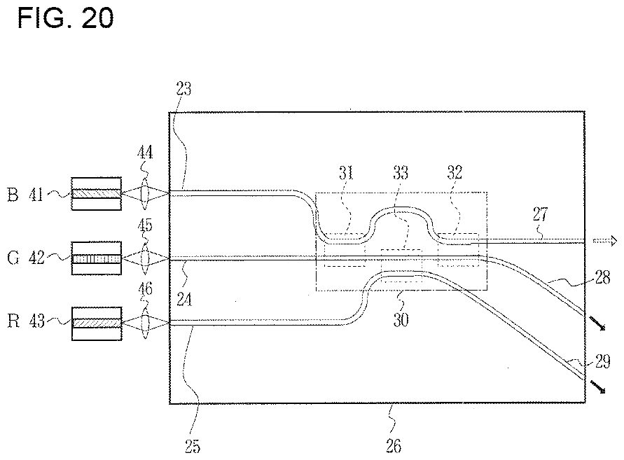

Next, the optical waveguide-type multiplexing light source optical device in Example 20 of the present invention is described in reference to FIG. 20, and the description relates to a light source module where the optical elements are omitted. This light source module is gained by providing condenser lenses 44 through 46 between the respective semiconductor lasers and the respective optical waveguides for light input in the above-described light source module in Example 14. As illustrated in FIG. 20, the blue semiconductor laser chip 41 is arranged on the entrance end surface of the optical waveguide 23 for light input, the green semiconductor laser chip 42 is arranged on the entrance end surface of the optical waveguide 24 for light input, and the red semiconductor laser chip 43 is arranged on the entrance end surface of the optical waveguide 25 for light input so that the respectively emitted light beams are condensed by the condenser lenses 44 through 46 so as to enter into the respective optical waveguides 23 through 25 for light input.

Here, a biconvex lens having a focal distance of 10 mm and a diameter of 3 mm is used as the condenser lenses 44 through 46. The distance between the emission ends of the blue semiconductor laser chip 41, the green semiconductor laser chip 42 and the red semiconductor laser chip 43 and the centers of condenser lenses 44 through 46 is 20 mm, and the distance between the centers of the condenser lenses 44 through 46 and the entrance ends of the optical waveguides 23 through 25 for light input is 20 mm.

As for the ratio of the quantity of light (light power) emitted from each optical waveguide 27 through 29 on the light emission side to the quantity of light that has entered in the case where light with a wavelength of 638 nm has entered into the optical waveguide 25 for light input, the ratio of the quantity of light emitted from the optical waveguide 27 on the light emission side that becomes an optical waveguide for light emission is 4.5% (the light attenuation is 13.5 dB), the ratio of quantity of light emitted from the optical waveguide 28 on the light emission side is 74%, and the ratio of quantity of light emitted from the optical waveguide 29 on the light emission side is 19%.

As for the ratio of the quantity of light (light power) emitted from each optical waveguide 27 through 29 on the light emission side to the quantity of light that has entered in the case where light with a wavelength of 520 nm has entered into the optical waveguide 24 for light input, the ratio of the quantity of light emitted from the optical waveguide 29 on the light emission side that becomes an optical waveguide for light emission is 4% (the light attenuation is 14 dB), the ratio of quantity of light emitted from the optical waveguide 28 on the light emission side is 95%, and the ratio of quantity of light emitted from the optical waveguide 29 on the light emission side is 1%.

As for the ratio of the quantity of light (light power) emitted from each optical waveguide 27 through 29 on the light emission side to the quantity of light that has entered in the case where light with a wavelength of 450 nm has entered into the optical waveguide 23 for light input, the ratio of the quantity of light emitted from the optical waveguide 27 on the light emission side that becomes an optical waveguide for light emission is 21.5% (the light attenuation is 6.7 dB), the ratio of quantity of light emitted from the optical waveguide 28 on the light emission side is 72.5%, and the ratio of quantity of light emitted from the optical waveguide 29 on the light emission side is 4%.

As described above, a light attenuation of 11.4 dB on average was gained. In addition, there was almost no light leakage from the middle of the optical waveguides and no stray light was caused in the middle of the multiplexers, and thus, high-quality output light was gained without being affected by stray light. In addition, the light beam from the emission end of the optical waveguide 29 on the light emission side that became an optical waveguide for light emission was able to be made to enter the MEMS mirror for two-dimensional scanning with light via a condenser lens in the same manner as in Example 17, and as a result of scanning with light, it was possible to project an image onto a screen.

### Example 21

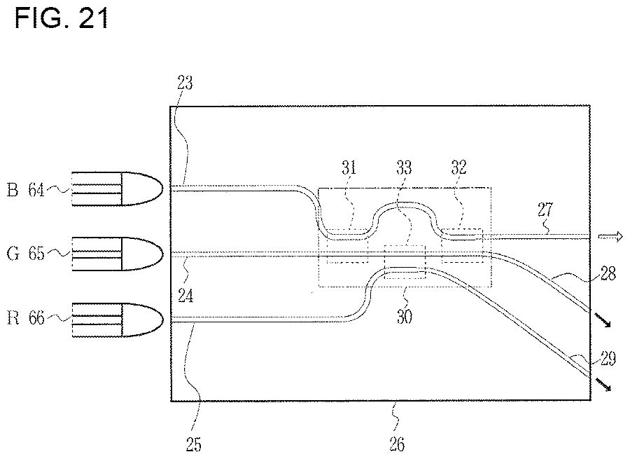

Next, the optical waveguide-type multiplexing light source optical device in Example 21 of the present invention is described in reference to FIG. 21, and the description relates to a light source module where the optical elements are omitted. This light source module is gained by replacing the semiconductor lasers with optical fibers with a lensed end in the above-described light source module in Example 14 where the remaining portions of the configuration are the same as in the light source module in Example 14.

As illustrated in FIG. 21, an optical fiber 64 with a lensed end through which blue light propagates is arranged on the entrance end surface of the optical waveguide 23 for light input, an optical fiber 65 with a lensed end through which green light propagates is arranged on the entrance end surface of the optical waveguide 24 for light input, and an optical fiber 66 with a lensed end through which red light propagates is arranged on the entrance end surface of the optical waveguide 25 for light input so that light can enter into the respective optical waveguides 23 through 25 for light input.

Here, an optical fiber with a lensed end having a fiber diameter of 125 μm, a beam spot diameter of 2.5 μm and a working distance of 14 μm through which light in a visible light range propagates in a single mode is used as the optical fibers 64 through 66 with a lensed end. The wavelength of light that propagates through the optical fiber 64 with a lensed end is 450 nm, the wavelength of light that propagates through the optical fiber 65 with a lensed end is 520 nm, and the wavelength of light that propagates through the optical fiber 66 with a lensed end is 638 nm.

In this case as well, almost the same characteristics as in Example 14 were gained. In addition, the light beam from the emission end of the optical waveguide 27 on the light emission side that became an optical waveguide for light emission was able to be made to enter the MEMS mirror for two-dimensional scanning with light via a condenser lens in the same manner as in Example 17, and as a result of scanning with light, it was possible to project an image onto a screen. Here, the optical fibers 64 through 66 with a lensed end were used; however, it was possible to gain similar results with regular optical fibers that are cut with an end surface, though the entrance efficiency was lower by 3 dB.

### Example 22

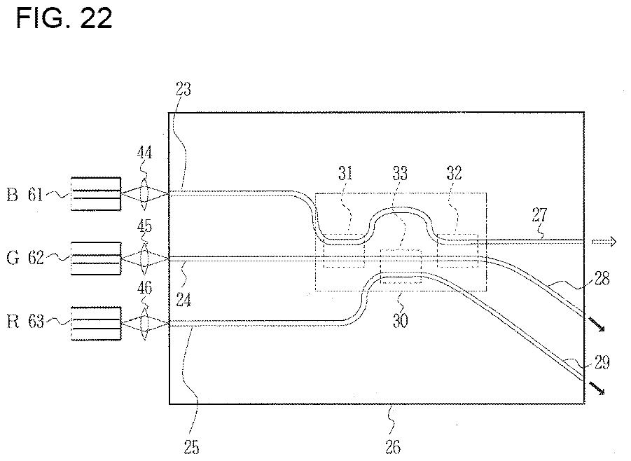

Next, the optical waveguide-type multiplexing light source optical device in Example 22 of the present invention is described in reference to FIG. 22, which shows a light source module without illustrating the optical elements in the optical waveguide-type optical multiplexing light source optical device. This light source module is gained by replacing the semiconductor lasers in the above-described light source module in Example 14 with optical fibers, and at the same time interposing condenser lenses, and the remaining portions of the configuration are the same as in the light source module in Example 14.

As illustrated in FIG. 22, an optical fiber 61 through which blue light propagates is arranged so as to face the entrance end surface of the optical waveguide 23 for light input, an optical fiber 62 through which green light propagates is arranged so as to face the entrance end surface of the optical waveguide 24 for light input, and an optical fiber 63 through which red light propagates is arranged so as to face the entrance end surface of the optical waveguide 25 for light input, and thus, the respectively emitted light beams are condensed through condenser lenses 44 through 46 so as to enter into the respective optical waveguides 23 through 25 for light input.

Here, optical fibers having a fiber diameter of 125 μm through which light in a visible light range propagates in a single mode are used as the optical fibers 61 through 63. Biconvex lenses having a focal distance of 10 mm and a diameter of 3 mm are used as the condenser lenses 44 through 46. The distance between the emission ends of the optical fibers 61 through 63 and the centers of the condenser lenses 44 through 46 is 20 mm, and the distance between the centers of the condenser lenses 44 through 46 and the entrance ends of the optical waveguides 23 through 25 for light input is 20 mm.

In this case as well, almost the same characteristics as in Example 14 were gained. In addition, the light beam from the emission end of the optical waveguide 27 on the light emission side that became an optical waveguide for light emission was able to be made to enter the MEMS mirror for two-dimensional scanning with light via a condenser lens in the same manner as in Example 17, and as a result of scanning with light, it was possible to project an image onto a screen.

### Example 23

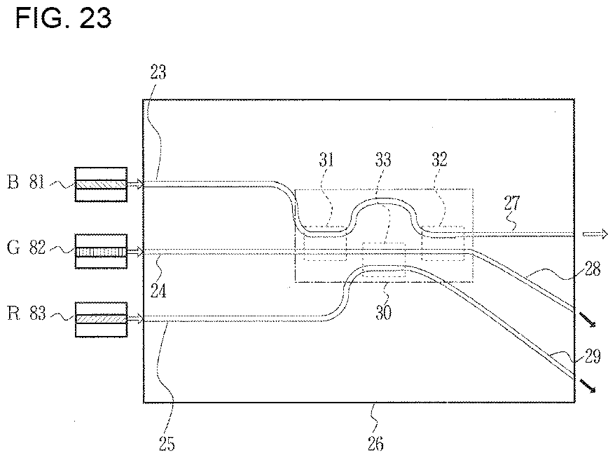

Next, the light source module in Example 23 of the present invention is described in reference to FIG. 23. The light source module in Example 23 is gained by using end surface emission-type light emitting diodes (LEDs) instead of the respective semiconductor lasers in the above-described light source module in Example 14. As illustrated in FIG. 23, a blue LED chip 81 for emitting light with a wavelength of 452 nm is arranged so as to face the entrance end surface of the optical waveguide 23 for light input, a green LED chip 82 for emitting light with a wavelength of 522 nm is arranged so as to face the entrance end surface of the optical waveguide 24 for light input, and a red LED chip 83 for emitting light with a wavelength of 640 nm is arranged so as to face the entrance end surface of the optical waveguide 25 for light input, and thus, the respectively emitted light beams enter into the respective optical waveguides 23 through 25 for light input.

As for the ratio of the quantity of light (light power) emitted from the respective optical waveguides 27 through 29 on the light emission side to the quantity of light that has entered in the case where light with a wavelength of 240 nm enters into the optical waveguide 25 for light input, the quantity ratio of light emitted from the optical waveguide 27 on the light emission side that becomes an optical waveguide for light emission is 5% (the light attenuation is 13 dB), the quantity ratio of light emitted from the optical waveguide 28 on the light emission side is 75%, and the quantity ratio of light emitted from the optical waveguide 29 on the light emission side is 18%.

As for the ratio of the quantity of light (light power) emitted from each optical waveguide 27 through 29 on the light emission side to the quantity of light that has entered in the case where light with a wavelength of 522 nm has entered into the optical waveguide 24 for light input, the ratio of the quantity of light emitted from the optical waveguide 27 on the light emission side that becomes an optical waveguide for light emission is 4% (the light attenuation is 14 dB), the ratio of quantity of light emitted from the optical waveguide 28 on the light emission side is 95%, and the ratio of quantity of light emitted from the optical waveguide 29 on the light emission side is 1%.

As for the ratio of the quantity of light (light power) emitted from each optical waveguide 27 through 29 on the light emission side to the quantity of light that has entered in the case where light with a wavelength of 452 nm has entered into the optical waveguide 23 for light input, the ratio of the quantity of light emitted from the optical waveguide 27 on the light emission side that becomes an optical waveguide for light emission is 20% (the light attenuation is 7 dB), the ratio of quantity of light emitted from the optical waveguide 28 on the light emission side is 73%, and the ratio of quantity of light emitted from the optical waveguide 29 on the light emission side is 4%.

As described above, a light attenuation of 11.3 dB on average was gained. In addition, there was almost no light leakage from the middle of the optical waveguides, and no stray light was caused in the middle of the multiplexer, and thus, a high-quality output light was gained without being affected by stray light. In addition, the light beam from the emission end of the optical waveguide 27 on the light emission side that became an optical waveguide for light emission was able to be made to enter the MEMS mirror for two-dimensional scanning with light via a condenser lens in the same manner as in Example 17, and as a result of scanning with light, it was possible to project an image onto a screen. Though end surface emission-type light emitting diodes are used in Example 22, other types of light emitting diodes, for example, surface emission-type light emitting diodes, may be used.

### Example 24

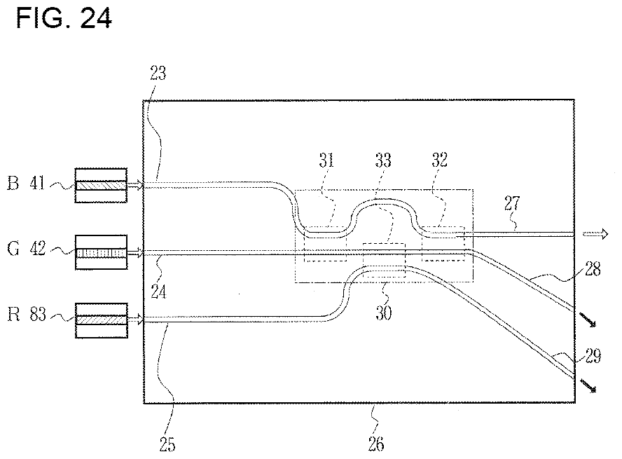

Next, the optical waveguide-type multiplexing light source optical device in Example 24 of the present invention is described in reference to FIG. 24. The optical waveguide-type multiplexing light source optical device in Example 24 is gained by replacing the red semiconductor laser chip with an end surface emission-type red LED chip in the above-described light source module in Example 14. As illustrated in FIG. 24, a blue semiconductor laser chip 41 for emitting light with a wavelength of 450 nm is arranged so as to face the entrance end surface of the optical waveguide 23 for light input, a green semiconductor laser chip 42 for emitting light with a wavelength of 520 nm is arranged so as to face the entrance end surface of the optical waveguide 24 for light input, and a red LED chip 83 for emitting light with a wavelength of 640 nm is arranged so as to face the entrance end surface of the optical waveguide 25 for light input, and thus, the respectively emitted light beams enter into the respective optical waveguides 23 through 25 for light input. Here, the red semiconductor laser chip is replaced with an LED; however, any of the other color semiconductor laser chips may be replaced with LEDs, or two semiconductor laser chips may be replaced with LEDs.

### Example 25

Next, the image formation device in Example 25 of the present invention is described. The basic configuration is the same as that of the image formation device illustrated in FIG. 30 with only a difference in the configuration of the optical waveguide-type optical multiplexer, and therefore, the description is made in reference to FIG. 30. The image formation device in Example 25 of the present invention is gained by replacing the optical waveguide-type optical multiplexer 30 in the image formation device in FIG. 30 with the above-described optical waveguide-type optical multiplexer 30 in Example 1. Here, the optical waveguide-type optical multiplexer 30 may be replaced with any of the optical waveguide-type multiplexers in Examples 2 through 13. In addition, the arrangement of the light sources may be changed to the arrangement in Example 6 or 7. Furthermore, as illustrated in FIGS. 19 through 24, lenses may be provided or the light sources may be replaced with optical fibers or optical fibers with a lensed end. Alternatively, at least some of the light sources may be replaced with an LED.

In this image formation device, in the same manner as in the prior art, a control unit 90 has a sub-control unit 91, an operation unit 92, an external interface (I/F) 93, an R laser driver 94, a G laser driver 95, a B laser driver 96 and a two-dimensional scanning driver 97. The sub-control unit 91 is formed of a microcomputer that includes a CPU, a ROM, a RAM and the like. The sub-control unit 91 generates an R signal, a G signal, a B signal, a horizontal signal and a vertical signal that become elements for synthesizing an image on the basis of the image data supplied from an external apparatus such as a PC via the external I/F 93. The sub-control unit 91 transmits the R signal to the R laser driver 94, the G signal to the G laser driver 95, and the b signal to the B laser driver 96, respectively. In addition, the sub-control unit 91 transmits the horizontal signal and the vertical signal to the two-dimensional scanning driver 97, and controls the current to be applied to the electromagnetic coil 86 so as to control the operation of the movable mirror unit 84.

The R laser driver 94 drives the red semiconductor laser chip 43 so that a red laser beam of which the optical quantity corresponds to the R signal from the sub-control unit 91 is generated. The G laser driver 95 drives the green semiconductor laser chip 42 so that a green laser beam of which the optical quantity corresponds to the G signal from the sub-control unit 91. The B laser driver 96 drives the blue semiconductor laser chip 41 so that a blue laser beam of which the light quantity corresponds to the B signal from the sub-control unit 91 is generated. It becomes possible to synthesize a laser beam having a desired color by adjusting the intensity ratio between the laser beams of the respective colors.

The respective laser beams generated in the blue semiconductor laser chip 41, the green semiconductor laser chip 42 and the red semiconductor laser chip 43 are multiplexed in the optical multiplexing unit 30 in the optical waveguide-type optical multiplexer, and after that reflected from the movable mirror unit 84 for two-dimensional scanning. An image is formed on a retina 100 as a result of scanning with the multiplexed laser beam that has been reflected from a concave reflection mirror 98 and passed through a pupil 99.

### Example 26

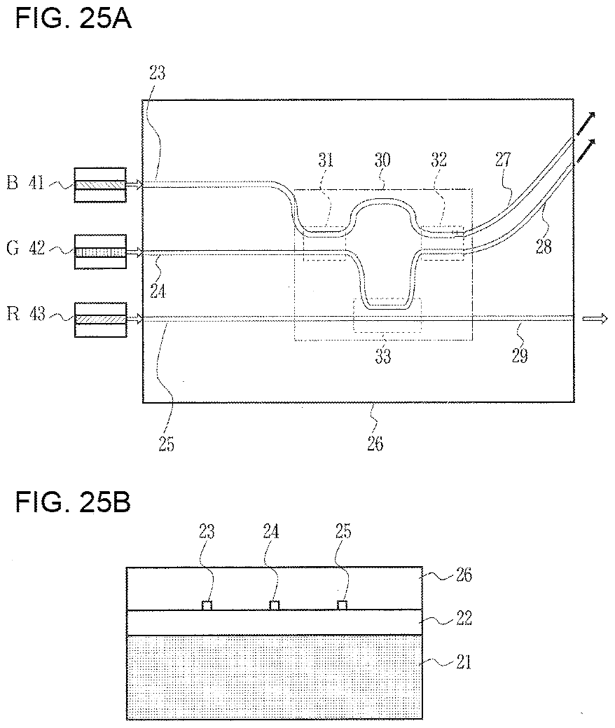

Next, the optical waveguide-type optical multiplexer in Example 26 of the present invention is described in reference to FIGS. 25A and 25B. FIGS. 25A and 25B are schematic diagrams illustrating the configuration of the optical waveguide-type optical multiplexer in Example 26 of the present invention. FIG. 25A is a schematic plan diagram, and FIG. 25B is a cross-sectional diagram on the input end side. Here, the optical waveguide-type optical multiplexer in Example 26 is the same as in Example 4, except that a curved portion is provided to the optical waveguide 24 for light input in the optical waveguide-type optical multiplexer in Example 4 of the present invention so as to provide an optical coupling part 33, and the optical waveguide 25 for light input is made to be an optical waveguide in straight form. Here, a light source module is illustrated by adding light sources for the purpose of easy understanding of the invention.

As illustrated in FIG. 25A, the optical waveguide 29 on the light emission side is used as the optical waveguide for light emission, and the optical waveguides 27 and 28 on the light emission side are used as optical waveguides for discarding light. As illustrated in FIG. 25B, each optical waveguide from among optical waveguides 23 through 25 for light input and optical waveguides 27 through 29 on the light emission side is formed of a lower clad layer, which is an SiO₂ layer 22 having a thickness of 20 μm provided on top of an Si substrate 21 having a thickness of 1 mm and a (100) surface as the main surface, a core layer having a width×a height of 2 μm×2 μm that is formed by etching Ge-doped SiO₂ glass provided on top of the SiO₂ layer 22, and an upper clad layer 26 that is made of an SiO₂ layer having a thickness of 9 μm provided on top of the core layer (the thickness on top of the SiO₂ layer becomes 11 μm). In this case, the difference in the refractive index between the core layer and the clad layer is 0.5%.

### Example 27

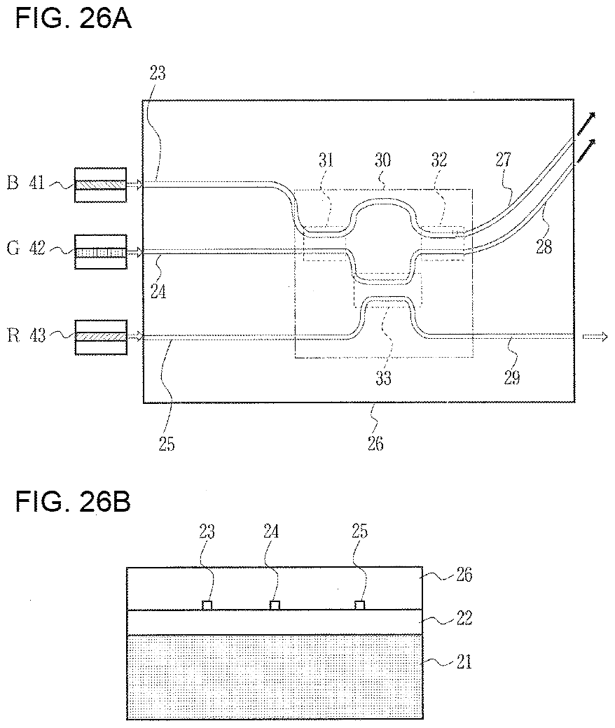

Next, the optical waveguide-type optical multiplexer in Example 27 of the present invention is described in reference to FIGS. 26A and 26B. FIGS. 26A and 26B are schematic diagrams illustrating the configuration of the optical waveguide-type optical multiplexer in Example 27 of the present invention. FIG. 26A is a schematic plan diagram, and FIG. 26B is a cross-sectional diagram on the input end side. Here, the optical waveguide-type optical multiplexer in Example 27 is the same as that in Example 4, except that a curved portion is provided to the optical waveguide 24 for light input, and at the same time, a curved portion is provided to the optical waveguide 25 for light input in the optical waveguide-type optical multiplexer in Example 4 of the present invention so as to provide an optical coupling part 33. Here again, a light source module is illustrated by adding light sources for the purpose of easy understanding of the invention.

As illustrated in FIG. 26A, the optical waveguide 29 on the light emission side is used as the optical waveguide for light emission, and optical waveguides 27 and 28 on the light emission side are used as the optical waveguide for discarding light. As illustrated in FIG. 26B, each optical waveguide from among optical waveguides 23 through 25 for light input and optical waveguides 27 through 29 on the light emission side is formed of a lower clad layer, which is an SiO₂ layer 22 having a thickness of 20 μm provided on top of an Si substrate 21 having a thickness of 1 mm and a (100) surface as the main surface, a core layer having a width×a height of 2 μm×2 μm that is formed by etching Ge-doped SiO₂ glass provided on top of the SiO₂ layer 22, and an upper clad layer 26 that is made of an SiO₂ layer having a thickness of 9 μm provided on top of the core layer (the thickness on top of the SiO₂ layer becomes 11 μm). In this case, the difference in the refractive index between the core layer and the clad layer is 0.5%.

### Example 28

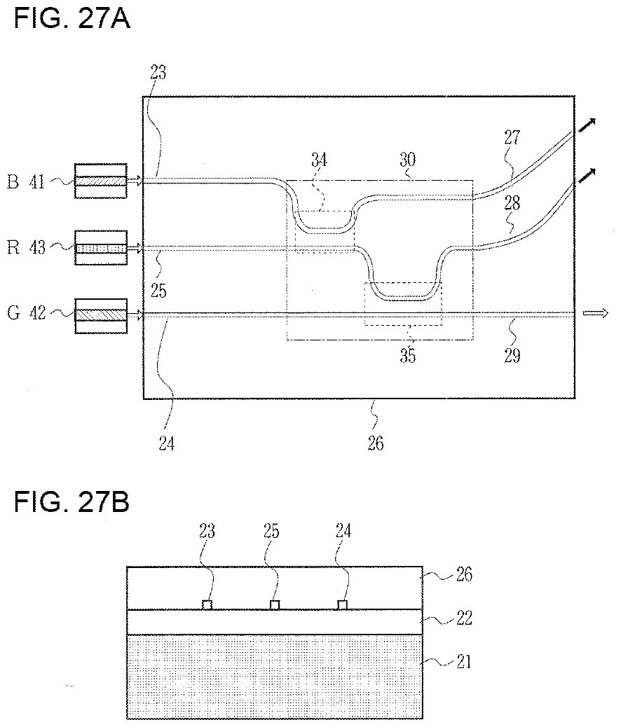

Next, the optical waveguide-type optical multiplexer in Example 28 of the present invention is described in reference to FIGS. 27A and 27B. FIGS. 27A and 27B are schematic diagrams illustrating the configuration of the optical waveguide-type optical multiplexer in Example 28 of the present invention. FIG. 27A is a schematic plan diagram, and FIG. 27B is a cross-sectional diagram on the input end side. Here again, a light source module is illustrated by adding light sources for the purpose of easy understanding of the invention. The optical waveguide-type optical multiplexer in Example 28 is basically the same as in Example 8, except that a curved portion is provided to the optical waveguide 25 for light input, and the optical waveguide 24 for light input is made to be an optical waveguide in straight form in the optical waveguide-type optical multiplexer in Example 8.

As illustrated in FIG. 27A, the optical waveguide 25 for light input for guiding red light having a large dispersion is placed in the middle, the optical waveguide 23 for light input for guiding blue light is optically coupled with the optical waveguide 25 for light input through the optical coupling part 34, and the optical waveguide 24 for light input for guiding green light is optically coupled with the optical waveguide 25 for light input in the optical coupling part 35 in a stage to the rear of the optical coupling part 34. The optical waveguide 25 for light input that guides red light is connected to the optical waveguide 28 on the light emission side where the greatest multiplexed output light power can be gained from among the optical waveguides on the light emission side. A light signal is outputted from the optical waveguide 29 on the light emission side that becomes an optical waveguide for light emission connected to the optical waveguide 24 for light input in a stage to the rear of the optical coupling part 35. in this case as well, the same characteristics as in Example 8 can be gained.

### REFERENCE SIGNS LIST

1 substrate
2 through 4 optical waveguide for light input
5 optical multiplexing unit
6₁, 6₁, 7 optical coupling part
8, 9, 10 optical waveguide on the light emission side
11₁, 11₂, 11₃ light source
12 bent portion
13₁, 13₂, 13₃, 13₄ optical waveguide for light input
14₁ through 14₆ optical coupling part
15₁, 15₂, 15₃, 15₄ signal light
21 Si substrate
22 lower clad layer
23 through 25 optical waveguide for light input
26 upper clad layer
27 through 29 optical waveguide on the light emission side
30 optical multiplexing unit
31 through 35, 37 optical coupling part
36 optical waveguide exclusively for discarding light
38 bent optical waveguide
39 Y-branched type multiplexer
41 blue semiconductor laser chip
42 green semiconductor laser chip
43 red semiconductor laser chip
44 through 46 lens
47 yellow semiconductor laser chip
48 optical waveguide for light input
50 optical multiplexing unit
51 optical waveguide exclusively for discarding light
52 through 54 optical coupling part
61 through 63 optical fiber
64 through 66 optical fiber with a lensed end
71 lens
72 optical fiber
73 optical fiber with a lensed end
74 MEMS mirror for two-dimensional optical multiplexing
75 photodiode for monitoring
81 blue LED chip
82 green LED chip
83 red LED chip
84 movable mirror unit
85 substrate
86 electromagnetic coil
90 control unit
91 sub-control unit
92 operation unit
93 external interface (I/F)
94 R laser driver
95 G laser driver
96 B laser driver
97 two-dimensional scanning driver
98 concave reflection mirror
99 pupil

1. An optical waveguide-type optical multiplexer, comprising:
a plurality of optical waveguides for light input into which light having different wavelengths enters from a plurality of light sources;
an optical multiplexer unit for multiplexing light that has propagated through the optical waveguides for light input; and
a plurality of optical waveguides on the light emission side for emitting light that has been multiplexed in the optical multiplexer unit, wherein
one of the optical waveguides on the light emission side excluding an optical waveguide on the light emission side in which the greatest output light power can be gained for each wavelength from among the optical waveguides on the light emission side in the case where the plurality of light sources is driven is used as an optical waveguide for light emission, and
the optical waveguides on the light emission side excluding the optical waveguides for light emission are not linear up to the emission end.

2. An optical waveguide-type optical multiplexer, comprising:
a plurality of optical waveguides for light input into which light having different wavelengths enters from three or more light sources;
an optical multiplexer unit for multiplexing light that has propagated through the optical waveguides for light input; and
a plurality of optical waveguides on the light emission side for emitting light that has been multiplexed in the optical multiplexer unit, wherein
an optical waveguide on the light emission side where the maximum output light power can be gained for at least one wavelength from among the optical waveguides on the light emission side excluding an optical waveguide on the light emission side where the greatest multiplexed output light power can be gained in the case where the three or more light sources are driven with the same output is used as an optical waveguide for light emission, and
the optical waveguides on the light emission side excluding the optical waveguide for light emission are not linear up to the emission end.

3. The optical waveguide-type optical multiplexer according to claim 1, wherein
the optical waveguide for light emission is an optical waveguide in linear form at least in a region excluding the proximity to the emission end, and
the optical waveguides on the light emission side excluding the optical waveguide for light emission are inclined relative to the propagation axis line in the optical multiplexer unit.

4. The optical waveguide-type optical multiplexer according to claim 3, wherein the optical waveguide for light emission is inclined at an angle of 85° to 95° relative to the optical waveguide in linear form in proximity to the emission end.

5. The optical waveguide-type optical multiplexer according to claim 1, wherein an optical waveguide on the light emission side excluding the optical waveguide for light emission is an optical waveguide exclusively for discarding light or an optical waveguide for monitoring.

6. The optical waveguide-type optical multiplexer according to claim 1, wherein the number of the optical waveguides on the light emission side is the same as the number of the optical waveguides for light input.

7. The optical waveguide-type optical multiplexer according to claim 1, wherein the number of the optical waveguides on the light emission side is smaller than the number of the optical waveguides for light input.

8. The optical waveguide-type optical multiplexer according to claim 1, wherein the optical multiplexer unit can multiplex at least light of three primary colors, red light, blue light and green light.

9. The optical waveguide-type optical multiplexer according to claim 1, wherein the direction in which light is guided in proximity to the input ends of the plurality of optical waveguides for light input is inclined at an angle of 85° to 95° relative to the propagation axis line in the optical multiplexer unit.

10. The optical waveguide-type optical multiplexer according to claim 1, wherein a first direction in which light is guided in proximity to the input end of at least one optical waveguide for light input from among the plurality of optical waveguides for light input is inclined at an angle of 85° to 95° relative to the propagation axis line in the optical multiplexer unit, and a second direction in which light is guided in proximity to the input ends of the remaining optical waveguides for light input from among the plurality of optical waveguides for light input is inclined at an angle of 85° to 95° relative to the propagation axis line in the optical multiplexer unit in such a manner as to face the first direction in which light is guided in proximity to the input ends of the optical waveguides for light input.

11. An optical waveguide-type multiplexing light source optical device, comprising:
a plurality of light sources;
a plurality of optical waveguides for light input into which light enters from the plurality of light sources;
an optical multiplexer unit for multiplexing light that has propagated through the optical waveguides for light input; and
a plurality of optical waveguides on the light emission side for emitting light that has been multiplexed in the optical multiplexer unit, wherein
one of the optical waveguides on the light emission side excluding an optical waveguide on the light emission side in which the greatest output light power can be gained for each wavelength from among the optical waveguides on the light emission side in the case where the plurality of light sources is driven is used as an optical waveguide for light emission, and
the optical waveguide-type multiplexing light source optical device further comprises an optical element that can be optically coupled with a signal light from the optical waveguide for light emission.

12. An optical waveguide-type multiplexing light source optical device, comprising:
three or more light sources for emitting light with different wavelengths;
a plurality of optical waveguides for light input into which light having different wavelengths enters from the three or more light sources;
an optical multiplexer unit for multiplexing light that has propagated through the optical waveguides for light input; and
a plurality of optical waveguides on the light emission side for emitting light that has been multiplexed in the optical multiplexer unit, wherein
an optical waveguide on the light emission side where the maximum output light power can be gained for at least one wavelength from among the optical waveguides on the light emission side excluding an optical waveguide on the light emission side where the greatest multiplexed output light power can be gained in the case where the three or more light sources are driven with the same output is used as an optical waveguide for light emission, and
the optical waveguide-type multiplexing light source optical device further comprises an optical element that can be optically coupled with a signal light from the optical waveguide for light emission.

13. The optical waveguide-type multiplexing light source optical device according to claim 11, wherein the optical element is an optical element that includes a condenser lens, an optical fiber or a combination thereof.

14. The optical waveguide-type multiplexing light source optical device according to claim 11, wherein the optical element is an optical element that includes at least an optical element for scanning with light.

15. The optical waveguide-type multiplexing light source optical device according to claim 11, wherein
the plurality of light sources are semiconductor lasers or light emitting diodes, and
the semiconductor lasers or the light emitting diodes are arranged so as to face the plurality of optical waveguides for light input directly or with condenser lenses in-between.

16. The optical waveguide-type multiplexing light source optical device according to claim 11, wherein light from the plurality of light sources is light emitted from a plurality of optical fibers.

17. The optical waveguide-type multiplexing light source optical device according to claim 11, wherein the light attenuation of the power that has been inputted into the optical waveguides for light input and is outputted from the optical waveguide for light emission is 5 dB to 40 dB.

18. The optical waveguide-type multiplexing light source optical device according to claim 11, wherein
the optical multiplexer unit comprises:
an optical waveguide in linear form for guiding green light;
an optical waveguide for guiding blue light that optically couples with the optical waveguide for guiding green light through two optical coupling parts; and
an optical waveguide for guiding red light that optically couples with the optical waveguide for guiding green light through a portion between the two optical coupling parts, wherein
either the optical waveguide for guiding blue light or the optical waveguide for guiding red light is connected to the optical waveguide for light emission.

19. The optical waveguide-type multiplexing light source optical device according to claim 11, wherein
the optical multiplexer unit comprises:
an optical waveguide having a curved portion for guiding green light;
an optical waveguide for guiding blue light that optically couples with the optical waveguide for guiding green light through two optical coupling parts located in front of and to the rear of the curved portion; and
an optical waveguide in linear form for guiding red light that optically couples with the optical waveguide for guiding green light through the curved portion, wherein
either the optical waveguide for guiding blue light or the optical waveguide for guiding red light is connected to the optical waveguide for light emission.

20. The optical waveguide-type multiplexing light source optical device according to claim 11, wherein
the optical multiplexer unit comprises:
an optical waveguide having a first curved portion for guiding green light;
an optical waveguide for guiding blue light that optically couples with the optical waveguide for guiding green light through two optical coupling parts located in front of and to the rear of the first curved portion; and
an optical waveguide for guiding red light having a second curved portion that optically couples with the optical waveguide for guiding green light through the first curved portion, wherein
either the optical waveguide for guiding blue light or the optical waveguide for guiding red light is connected to the optical waveguide for light emission.

21. The optical waveguide-type multiplexing light source optical device according to claim 11, wherein
the optical multiplexer unit comprises:
an optical waveguide in linear form for guiding red light;
an optical waveguide for guiding blue light that optically couples with the optical waveguide for guiding green light; and
an optical waveguide for guiding green light that optically couples with the optical waveguide for guiding red light, wherein
either the optical waveguide for guiding blue light or the optical waveguide for guiding green light that optically couples with the optical multiplexer unit in a rear stage relative to the direction in which light propagates is connected to the optical waveguide for light emission.

22. The optical waveguide-type multiplexing light source optical device according to claim 11, wherein
the optical multiplexer unit comprises:
an optical waveguide having a curved portion for guiding red light;
an optical waveguide in linear form for guiding green light that optically couples with the optical waveguide for guiding red light through the curved portion; and
an optical waveguide for guiding blue light that optically couples with the optical waveguide for guiding red light through a region excluding the curved portion, wherein
either the optical waveguide for guiding blue light or the optical waveguide for guiding green light that optically couples with the optical multiplexer unit in a rear stage relative to the direction in which light propagates is connected to the optical waveguide for light emission.

23. The optical waveguide-type multiplexing light source optical device according to claim 11, wherein
the optical waveguides on the light emission side are provided on a substrate,
the emission ends of the optical waveguides on the light emission side excluding the optical waveguide for light emission are located along a first side of the substrate, and
the emission end of the optical waveguide for light emission is located along a second side that crosses the first side of the substrate.

24. The optical waveguide-type multiplexing light source optical device according to claim 11, wherein the direction of the optical waveguide for light emission agrees with the propagation axis line in the optical multiplexer unit at a crossing angle within +/−10°.

25. An image projection devise, comprising:
the optical waveguide-type multiplexing light source optical device according to claim 14; and
an image formation unit for projecting onto a projection surface an image scanned with light that has been multiplexed by the optical element for scanning with light in the optical waveguide-type multiplexing light source optical device.
